(19) United States
(12) Patent Application Publication
(10) Pub. No.: US 2025/0107075 A1
(43) Pub. Date: Mar. 27, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Kyunghwan KIM, Suwon-si (KR); Joongchan SHIN, Suwon-si (KR); Hyungeun CHOI, Suwon-si (KR); Taegyu KANG, Suwon-si (KR); Keunui KIM, Suwon-si (KR); Bowon YOO, Suwon-si (KR)

(73) Assignee: Samsung Electronics Co., Ltd., Suwon-si (KR)

(21) Appl. No.: 18/809,859

(22) Filed: Aug. 20, 2024

(30) Foreign Application Priority Data
Sep. 27, 2023 (KR) 10-2023-0131172

(51) Int. Cl. H10B 12/00

(52) U.S. Cl. CPC H10B 12/488; H10B 12/315; H10B 12/482; H10B 12/50

(57) ABSTRACT

A semiconductor device includes a substrate including a cell array area and an interface area, bit lines on the cell array area and extending in a first horizontal direction, back gate lines on the bit lines and extending in a second direction, insulating blocks on the interface area and each overlapping the back gate lines in the second direction, word lines among which each pair of two adjacent word lines are on both sides of a corresponding back gate line, respectively, and extending on a sidewall of a corresponding insulating block, active semiconductor layers each between a corresponding back gate line and a corresponding word line on the cell array area and having one end electrically connected to a corresponding bit line, and a word line contact on the interface area and on a corresponding word line and a corresponding insulating block adjacent thereto.

### CROSS-REFERENCE TO RELATED APPLICATION

This application is based on and claims priority under 35 U.S.C. § 119 to Korean Patent Application No. 10-2023-0131172, filed on Sep. 27, 2023, in the Korean Intellectual Property Office, the disclosure of which is incorporated by reference herein in its entirety.

### BACKGROUND

The inventive concepts relate to semiconductor devices and/or methods of manufacturing the same, and more particularly, to semiconductor devices including a vertical channel transistor and/or methods of manufacturing the same.

With the downscaling of semiconductor devices, the size of dynamic random-access memory (DRAM) devices is also decreasing. In a DRAM device having a 1T-1C structure in which one capacitor is connected to one transistor, there is a problem in which leakage current through the channel area increases as the DRAM device becomes smaller. To reduce leakage current, a vertical channel transistor including a channel layer extending in the vertical direction has been proposed.

### SUMMARY

Some example embodiments of the inventive concepts provide semiconductor devices with improved electrical performance.

Some example embodiments of the inventive concepts provide methods of manufacturing a semiconductor device with improved electrical performance.

According to an example embodiment of the inventive concepts, a semiconductor device may include a substrate including a cell array area and an interface area, the cell array area being at at least one side of the cell array area, a plurality of bit lines on the cell array area of the substrate and extending in a first horizontal direction parallel to an upper surface of the substrate, a plurality of back gate lines being at a higher vertical level than the plurality of bit lines and extending in a second horizontal direction intersecting the first horizontal direction, a plurality of insulating blocks on the interface area of the substrate and each of the plurality of insulating blocks overlapping a corresponding one of the plurality of back gate lines in the second horizontal direction, a plurality of word lines among which each pair of two adjacent word lines are on two opposite sides of a corresponding one of the plurality of back gate lines, respectively, each of the plurality of word lines extending on a sidewall of a corresponding one of the plurality of insulating blocks in the second horizontal direction, a plurality of active semiconductor layers, each of the plurality of active semiconductor layers being between an adjacent pair of one of the plurality of back gate lines and one of the plurality of word lines on the cell array area of the substrate, each of the plurality of active semiconductor layers having one end electrically connected to a corresponding one of the plurality of bit lines, and a word line contact on the interface area of the substrate, the word line contact being on a corresponding word line, among the plurality of word lines, and being on a corresponding insulating block, among the plurality of insulating blocks, adjacent to the corresponding word line.

According to an example embodiment of the inventive concepts, a semiconductor device may include a substrate including a cell array area and an interface area, the interface area being at at least one side of the cell array area, a plurality of bit lines on the cell array area of the substrate and extending in a first horizontal direction parallel to an upper surface of the substrate, a plurality of back gate lines being at a higher vertical level than the plurality of bit lines and extending in a second horizontal direction intersecting the first horizontal direction, a plurality of insulating blocks on the interface area of the substrate and each of the plurality of insulating blocks overlapping a corresponding one of the plurality of back gate lines in the second horizontal direction, a plurality of word lines among which each pair of two adjacent word lines are on two opposite sides of a corresponding one of the plurality of back gate lines, respectively, each of the plurality of word lines extending on a sidewall of a corresponding one of the plurality of insulating blocks in the second horizontal direction, a plurality of active semiconductor layers, each of the plurality of active semiconductor layers being between an adjacent pair of one of the plurality of back gate lines and one of the plurality of word lines on the cell array area of the substrate, each of the plurality of active semiconductor layers having one end electrically connected to a corresponding one of the plurality of bit lines, a back gate contact on the interface area of the substrate and on a corresponding one of the plurality of back gate lines, and a word line contact on the interface area of the substrate and electrically connected to a corresponding one of the plurality of word lines at a position vertically overlapping a corresponding one of the plurality of insulating blocks, wherein the word line contact is spaced apart from a corresponding one of the plurality of back gate lines in the second horizontal direction.

According to an example embodiment of the inventive concepts, a semiconductor device may include a substrate including a cell array area and an interface area, the interface area being at at least one side of the cell array area, a peripheral circuit transistor on an upper surface of the substrate, a plurality of bit lines on the cell array area of the substrate, being at a vertical level higher than the peripheral circuit transistor, and extending in a first horizontal direction parallel to the upper surface of the substrate, a plurality of back gate lines at a higher vertical level than the plurality of bit lines and extending in a second horizontal direction intersecting the first horizontal direction, a plurality of word lines among which each pair of two adjacent word lines are on two opposite sides of a corresponding one of the plurality of back gate lines, respectively, the plurality of word lines extending in the second horizontal direction, a plurality of active semiconductor layers, each of the plurality of active semiconductor layers being between an adjacent pair of one the plurality of back gate lines and one of the plurality of word lines on the cell array area of the substrate, each of the plurality of active semiconductor layers having one end electrically connected to a corresponding one of the plurality of bit lines, a plurality of dummy active semiconductor layers between each of the plurality of back gate lines and one of the plurality of word lines adjacent thereto, and on the interface area of the substrate, a back gate insulating layer between sidewalls of each of the plurality of back gate lines and a corresponding one of the plurality of active semiconductor layer adjacent thereto, an insulating block on the interface area of the substrate, spaced apart from a corresponding one of the plurality of back gate lines, and having a sidewall aligned with the back gate insulating layer, a back gate contact on the interface area of the substrate and on a corresponding one of the plurality of back gate lines, and a word line contact on the interface area of the substrate and electrically connected to a corresponding one of the plurality of word lines at a position vertically overlapping a corresponding one of the plurality of insulating blocks.

### BRIEF DESCRIPTION OF THE DRAWINGS

Some example embodiments of the inventive concepts will be more clearly understood from the following detailed description taken in conjunction with the accompanying drawings in which:

FIG. 1 is a schematic diagram showing a semiconductor device according to an example embodiment;

FIG. 2 is a layout diagram of part II of FIG. 1;

FIG. 3 is a cross-sectional view taken along line A-A′ in FIG. 2;

FIG. 4 is a cross-sectional view taken along line B-B′in FIG. 2;

FIG. 5 is a cross-sectional view taken along line C-C′ in FIG. 2;

FIG. 6 is an enlarged view of portion CX1 of FIG. 4;

FIG. 7 is a plan view showing a semiconductor device according to an example embodiment;

FIG. 8 is a plan view showing a semiconductor device according to an example embodiment;

FIG. 9 is a plan view showing a semiconductor device according to an example embodiment;

FIGS. 10A to 20D are schematic diagrams showing a method of manufacturing a semiconductor device, according to an example embodiment, wherein FIGS. 10A, 11A, 12A, 13A, 14A, 15A, 16A, 17A, and 20A are top views based on the process sequence, FIGS. 10B, 11B, 12B, 13B, 14B, 15B, 16B, 17B, 18A, 19A, and 20B are cross-sectional views taken along line A-A′ in FIG. 2 based on the process sequency, FIGS. 10C, 11C, 12C, 13C, 14C, 15C, 16C, 17C, 18B, 19B, and 20C are cross-sectional views taken along line B-B′ in FIG. 2, and FIG. 20D is a cross-sectional view taken along line C-C′ in FIG. 2 based on the process sequency; and

FIGS. 21A to 22C are schematic diagrams showing a method of manufacturing a semiconductor device, according to an example embodiment, wherein FIGS. 21A and 22B are top views based on the process sequence, FIGS. 21B and 22B are cross-sectional views taken along line A-A′ in FIG. 2 based on the process sequence, and FIGS. 21C and 22C are cross-sectional views taken along line B-B′in FIG. 2 based on the process sequence.

### DETAILED DESCRIPTION

As used herein, expressions such as “at least one of,” when preceding a list of elements, modify the entire list of elements and do not modify the individual elements of the list. Thus, for example, “at least one of A, B, or C,” “at least one of A, B, and C,” and “at least one selected from A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

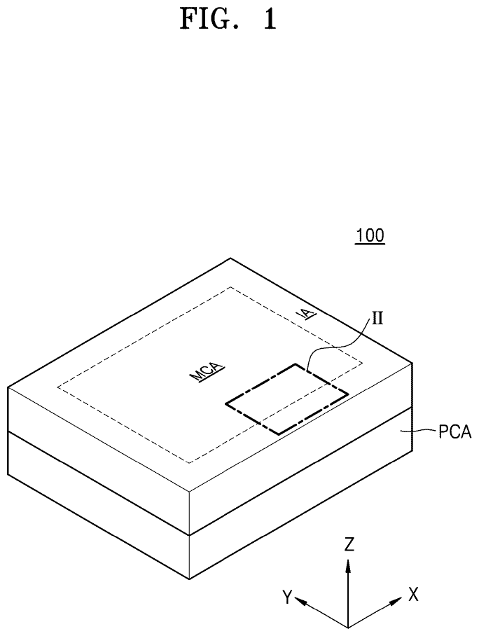

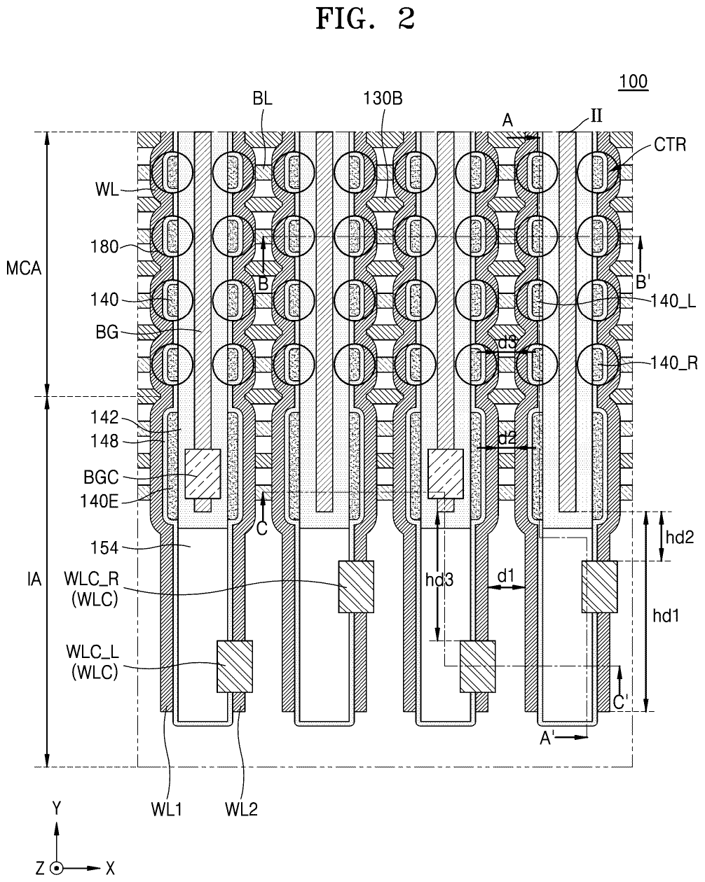

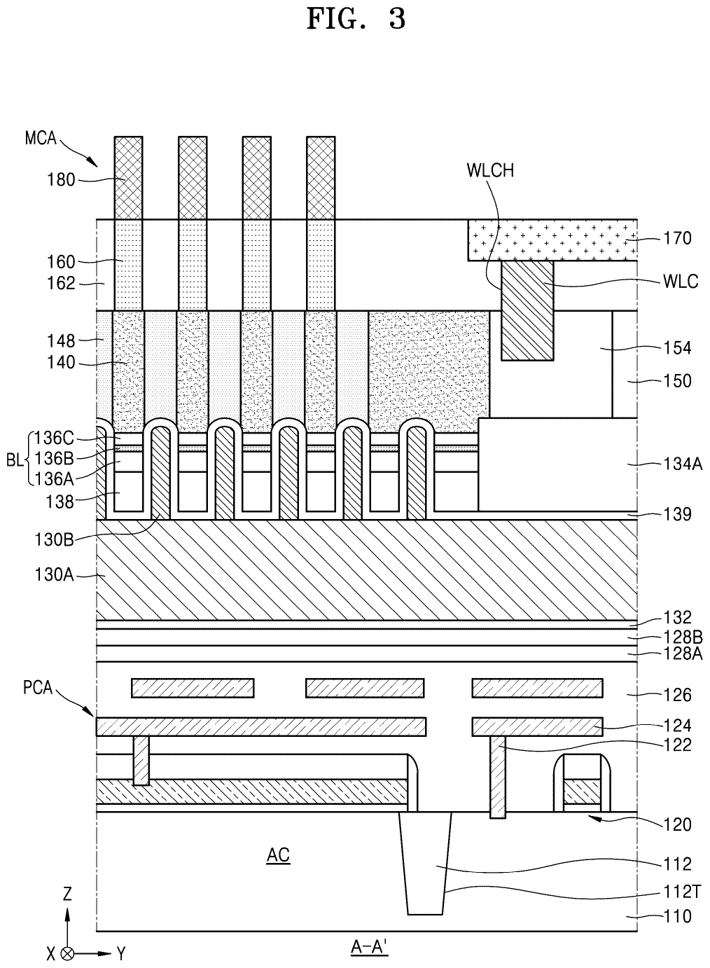

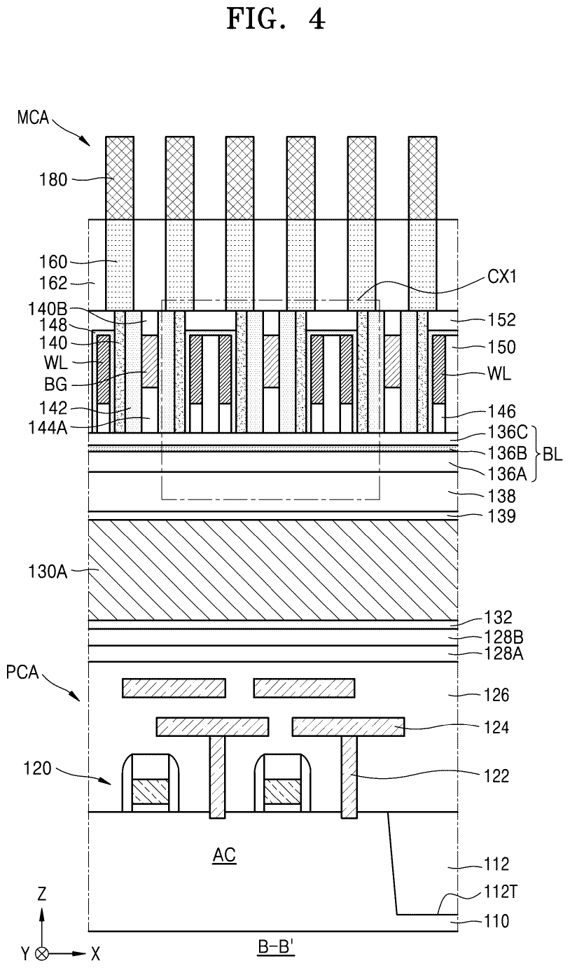

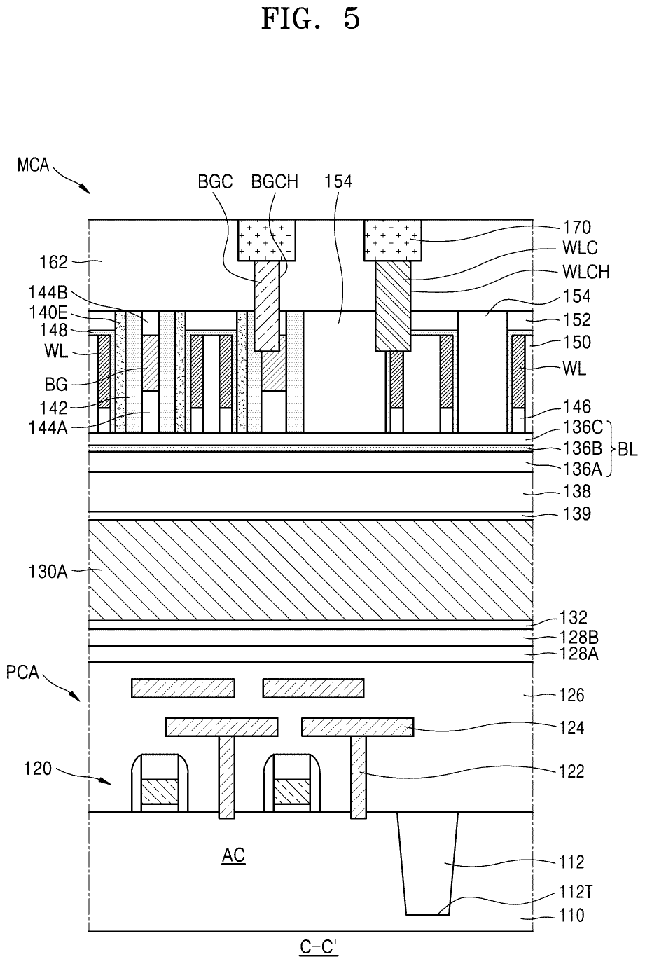

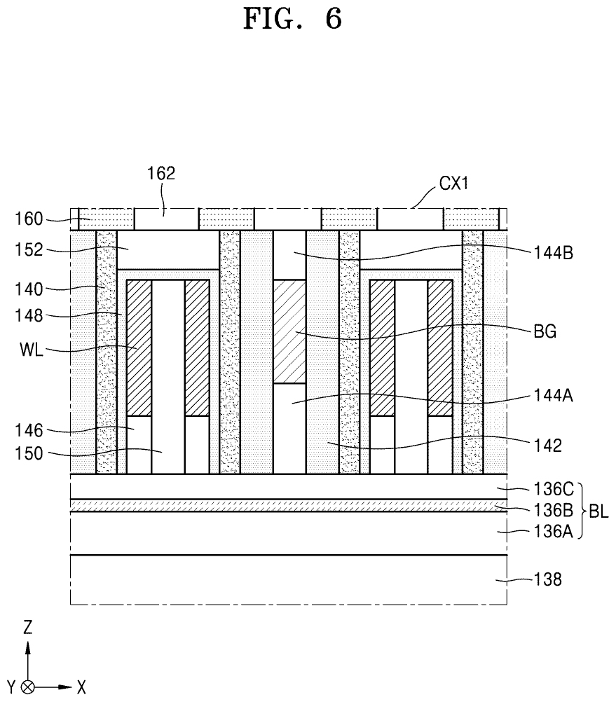

FIG. 1 is a schematic diagram showing a semiconductor device 100 according to an example embodiment. FIG. 2 is a layout diagram of part II of FIG. 1. FIG. 3 is a cross-sectional view taken along line A-A′ in FIG. 2. FIG. 4 is a cross-sectional view taken along line B-B′in FIG. 2. FIG. 5 is a cross-sectional view taken along line C-C′ in FIG. 2. FIG. 6 is an enlarged view of portion CX1 of FIG. 4.

Referring to FIGS. 1 to 6, the semiconductor device 100 may include a cell array area MCA and a peripheral circuit area PCA arranged at different vertical levels. The peripheral circuit area PCA and the cell array area MCA may overlap with each other in the vertical direction. For example, as shown in FIG. 1, the cell array area MCA may be disposed on the peripheral circuit area PCA, and the semiconductor device 100 may have a cell over periphery (COP) structure. In some example embodiments, an interface area IA may be disposed at at least one side of the cell array area MCA. In some example embodiments, as shown in FIG. 1, the cell array area MCA may be surrounded by the interface area IA in a plan view.

In some example embodiments, the cell array area MCA may be a memory cell area of a DRAM device, and the peripheral circuit area PCA may be a core area or a peripheral circuit area of a dynamic random-access memory (DRAM) device. For example, the peripheral circuit area PCA may include a peripheral circuit transistor 120 (see FIG. 3) for transmitting signals and/or power to a memory cell array included in the cell array area MCA. In some example embodiments, the peripheral circuit transistor 120 may form various circuits, such as a command decoder, control logic, address buffer, row decoder, column decoder, sense amplifier, and/or data input/output circuit.

As shown in FIG. 2, in the cell array area MCA, a plurality of word lines WL and a plurality of back gate lines BG may be alternately arranged to extend in a second horizontal direction Y. Additionally, a plurality of bit lines BL may extend in a first horizontal direction X. A plurality of cell transistors CTR may be disposed between each of the plurality of word lines WL and a back gate line BG adjacent thereto on the plurality of bit lines BL. The plurality of cell transistors CTR may be arranged in a matrix form in the first horizontal direction X and the second horizontal direction Y. A plurality of storage nodes 180 may be disposed on cell transistors CTR, respectively.

The interface area IA may be an area where contacts, vias, wiring, etc. are formed for electrical connection between the memory cell array included in the cell array area MCA and the peripheral circuit transistors 120 included in the peripheral circuit area PCA. For example, the word line WL, the back gate line BG, and the bit line BL may extend from the cell array area MCA to the interface area IA, and in the interface area IA, a word line contact WLC, a back gate contact BGC, and a bit line contact may be arranged to be connected to the word line WL, the back gate line BG, and the bit line BL, respectively.

The peripheral circuit area PCA may include a substrate 110 and a peripheral circuit transistor 120 disposed on the substrate 110.

The substrate 110 may include silicon, for example, single crystalline silicon, polycrystalline silicon, or amorphous silicon. In some other example embodiments, the substrate 110 may include at least one selected from Ge, SiGe, SiC, GaAs, InAs, and InP. A device isolation trench 112T may be formed in the substrate 110, and a device isolation film 112 may be formed within the device isolation trench 112T. An active area AC may be defined by the device isolation layer 112.

A peripheral circuit transistor 120 may be disposed on the active area AC of the substrate 110. The peripheral circuit transistor 120 may include at least one of a planar transistor, a fin field effect transistor (FinFET) transistor, a multi-bridge channel transistor, and a buried channel array transistor.

A peripheral circuit contact 122 and a peripheral circuit wiring layer 124 may be disposed on the substrate 110, and the peripheral circuit contact 122 and the peripheral circuit wiring layer 124 may be electrically connected to the peripheral circuit transistor 120. An interlayer insulating film 126 covering the peripheral circuit transistor 120, the peripheral circuit contact 122, and the peripheral circuit wiring layer 124 may be disposed on the substrate 110.

The peripheral circuit transistor 120 may be configured to apply a driving signal or driving voltage to at least one of a bit line BL, a word line WL, or a back gate line BG disposed in a cell array area MCA that vertically overlaps the peripheral circuit area PCA.

A first bonding insulating layer 128A and a second bonding insulating layer 128B may be sequentially disposed on the interlayer insulating film 126. The first bonding insulating layer 128A and the second bonding insulating layer 128B may be used to attach the peripheral circuit area PCA and the cell array area MCA, which have been formed on separate wafers, to each other by a bonding method. In some example embodiments, the first bonding insulating layer 128A and the second bonding insulating layer 128B may be omitted.

A first shield layer 130A may be disposed on the second bonding insulating layer 128B. The first shield layer 130A may include Ti, TiN, Ta, TaN, Mo, MoN, Ru, W, WN, Co, TiSiN, WSiN, polysilicon, or a combination thereof. A first insulating layer 132 may be disposed between the first shield layer 130A and the second bonding insulating layer 128B.

A plurality of bit lines BL extending in the first horizontal direction X may be disposed on the first shield layer 130A. In some example embodiments, the bit line BL may include Ti, TiN, Ta, TaN, Mo, MoN, Ru, W, WN, Co, TiSiN, WSiN, polysilicon, or a combination thereof.

In some example embodiments, as shown in FIG. 3, the bit line BL may include a first bit line conductive layer 136A, a second bit line conductive layer 136B, and a third bit line conductive layer 136C. In some example embodiments, the first bit line conductive layer 136A may include a metal material (e.g., tungsten or ruthenium), the second bit line conductive layer 136B may include titanium nitride or metal silicide, and the third bit line conductive layer 136C may include polysilicon.

A plurality of bit line capping layers 138 may be disposed on the bottom surfaces of the bit lines BL and vertically between the first shield layer 130A and the plurality of bit lines BL), respectively.

An insulating liner 139 may be disposed between the plurality of bit lines BL. For example, the insulating liner 139 may be conformally disposed on the sidewalls of the plurality of bit lines BL.

A second shield layer 130B may be disposed in the space between the plurality of bit lines BL on the insulating liner 139. The insulating liner 139 is between the second shield layer 130B and the adjacent bit line BL such that the second shield layer 130B and the bit line BL adjacent thereto may not be electrically connected to each other. The bottom surface of the second shield layer 130B may contact an upper surface of the first shield layer 130A.

In some example embodiments, the second shield layer 130B may include Ti, TiN, Ta, TaN, Mo, MoN, Ru, W, WN, Co, TiSiN, WSiN, polysilicon, or a combination thereof. In other example embodiments, the second shield layer 130B may be omitted and an air space may be disposed in the space between adjacent bit lines BL (for example, instead of the second shield layer 130B).

The plurality of back gate lines BG may be disposed on the plurality of bit lines BL and the insulating liner 139, and extend in the second horizontal direction Y. The plurality of word lines WL may be disposed on both sides of each of the plurality of back gate lines BG, and extend in the second horizontal direction Y. A plurality of active semiconductor layers 140 may be disposed between a corresponding one of the plurality of back gate lines BG and the word line WL adjacent thereto. For example, the plurality of active semiconductor layers 140 may be arranged to be spaced apart in the first horizontal direction X between one back gate line BG and one word line WL adjacent thereto. The plurality of active semiconductor layers 140 may have a relatively large height in a vertical direction Z and may correspond to the channel area of the vertical channel transistor.

In some example embodiments, the plurality of back gate lines BG may include polysilicon, Ti, TiN, Ta, TaN, Mo, MoN, Ru, W, WN, Co, TiSiN, WSiN, or a combination thereof.

A back gate insulating layer 142 may be arranged to extend in the second horizontal direction Y on both sides of each of the plurality of back gate lines BG. In some example embodiments, the back gate insulating layer 142 may include at least one of silicon oxide, silicon nitride, or high-k metal oxide.

In some example embodiments, the back gate insulating layer 142 may be made of at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

A first back gate capping layer 144A and a second back gate capping layer 144B may be disposed on the lower and upper surfaces of each of the plurality of back gate lines BG, respectively. For example, the first back gate capping layer 144A may be disposed between the bit line BL and the back gate line BG, and both sidewalls of the first back gate capping layer 144A may contact the back gate insulating layer 142. The second back gate capping layer 144B may be disposed on the upper surface of the bit line BL, and both sidewalls of the second back gate capping layer 144B may be in contact with the back gate insulating layer 142.

The plurality of active semiconductor layers 140 may be arranged in a matrix form by being spaced apart in the first horizontal direction X and the second horizontal direction Y, and each of the plurality of active semiconductor layers 140 may extend in the vertical direction Z on the upper surface of the bit line BL. In some example embodiments, the plurality of active semiconductor layers 140 may include a semiconductor material (e.g., silicon, germanium, or silicon germanium).

As shown in FIG. 2, the plurality of active semiconductor layers 140 may include a first active semiconductor layer 140_L disposed on the first side of each of the plurality of back gate lines BG. The plurality of active semiconductor layers 140 may also be disposed on the second side of each of the plurality of back gate lines BG and may include a second active semiconductor layer 140_R disposed adjacent to the first active semiconductor layer 140_L in the first horizontal direction X. The first active semiconductor layer 140_L and the second active semiconductor layer 140_R may have mirror symmetrical shapes with respect to each other. For example, the first active semiconductor layer 140_L and the second active semiconductor layer 140_R may have mirror symmetrical shapes with respect to each other with respect to the center line of the back gate line BG disposed therebetween (e.g., with respect to the center line of the back gate line BG extending in the second horizontal direction Y).

A gate insulating layer 148 may be disposed on the sidewalls of the plurality of active semiconductor layers 140. The gate insulating layer 148 may be disposed between the active semiconductor layer 140 and the word line WL adjacent thereto and may extend onto the upper surface of the word line WL. In some example embodiments, the gate insulating layer 148 may include at least one of silicon oxide, silicon nitride, or high-k metal oxide.

In some example embodiments, the gate insulating layer 148 may be made of at least one material selected from hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicate (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

The plurality of word lines WL may extend in the second horizontal direction Y on the sidewall of the gate insulating layer 148. The upper surfaces of the plurality of word lines WL may be covered by the gate insulating layer 148, and a word line capping layer 146 may be disposed on the bottom surface of each of the plurality of word lines WL. For example, the word line capping layer 146 may be between the bottom surfaces of the plurality of word lines WL and the bit line BL.

In some example embodiments, the word line WL may include Ti, TiN, Ta, TaN, Mo, Ru, W, WN, TiSiN, WSiN, polysilicon, or a combination thereof. In some example embodiments, the word line capping layer 146 may include silicon nitride.

The plurality of word lines WL may include a first word line WL1 disposed on a first side of one back gate line BG and a second word line WL2 disposed on a second side of the one back gate line BG. For example, the first word line WL1 may cover the first active semiconductor layer 140_L on the first side of one back gate line BG and may extend in the second horizontal direction Y, and the second word line WL2 may cover the second active semiconductor layer 140_R on the second side of one back gate line BG and may extend in the second horizontal direction Y.

In some example embodiments, in the cell array area MCA, the first word line WL1 and the second word line WL2 may be spaced apart from each other with the back gate line BG, the back gate insulating layer 142, the first active semiconductor layer 140_L, the second active semiconductor layer 140_R, and the gate insulating layer 148 therebetween and may extend in the second horizontal direction Y. In the interface area IA, the first word line WL1 and the second word line WL2 may be spaced apart from each other with the back gate line BG, the back gate insulating layer 142, a dummy active semiconductor layer 140E, and the gate insulating layer 148 therebetween may extend in a second horizontal direction Y.

A first edge insulating layer 134A may be disposed on sidewalls of the plurality of bit lines BL (e.g., on a sidewall of an innermost one of the plurality of bit lines BL) in the interface area IA.

Storage contacts 160 may be disposed on the plurality of active semiconductor layers 140. In some example embodiments, the storage contacts 160 may be arranged in a matrix form in the first horizontal direction X and the second horizontal direction Y. In some example embodiments, the storage contact 160 may include Ti, TiN, Ta, TaN, Mo, Ru, W, WN, TiSiN, WSiN, polysilicon, or a combination thereof. In some example embodiments, the storage contact 160 may have a double-layer structure including a lower contact disposed on the active semiconductor layer 140 and an upper contact disposed on the lower contact, the lower contact may include polysilicon doped with impurities, and the upper contact may include at least one of Ti, TiN, Ta, TaN, Mo, Ru, W, WN, TiSiN, and WSiN. The contact isolation insulating layer 162 may surround the sidewall of the storage contact 160.

A storage node 180 may be placed on the storage contact 160. In some example embodiments, the storage node 180 may be a metal-insulator-metal (MIM) capacitor. For example, the storage node 180 may include a MIM capacitor, which includes a lower electrode, a capacitor dielectric layer, and an upper electrode. The lower electrode may be disposed on the storage contact 160, and the capacitor dielectric layer and the upper electrode may be arranged to conformally cover the lower electrode. In other example embodiments, the storage node 180 may include memory components, such as variable resistance memory elements, phase change memory elements, or magnetic memory elements.

The dummy active semiconductor layer 140E may be disposed at the same vertical level as the plurality of active semiconductor layers 140 in the interface area IA. The dummy active semiconductor layer 140E may include the same material as the active semiconductor layer 140 and may include a semiconductor material, such as silicon, germanium, or silicon germanium. The dummy active semiconductor layer 140E may extend in the second horizontal direction Y on the back gate line BG and a sidewall of the back gate insulating layer 142.

The back gate contact BGC may be disposed on the back gate line BG in the interface area IA. The back gate contact BGC may be disposed on a portion of the back gate line BG adjacent to the dummy active semiconductor layer 140E. For example, the back gate contact BGC may be arranged to vertically overlap the back gate line BG and the back gate insulating layer 142 adjacent to the dummy active semiconductor layer 140E. The back gate contact BGC may be disposed in a back gate contact hole BGCH extending through the contact isolation insulating layer 162 and electrically connected to the back gate line BG. A sidewall of the back gate contact BGC may be surrounded by a contact isolation insulating layer 162, and a wiring layer 170 may be disposed on the upper surface of the back gate contact BGC.

An insulating block 154 may be disposed between the first word line WL1 and the second word line WL2 in the interface area IA. The gate insulating layer 148 and the word line WL may be disposed on a sidewall of the insulating block 154.

The insulating block 154 may overlap the back gate line BG and the back gate insulating layer 142 disposed on both sides of the back gate line BG in the second horizontal direction Y. For example, the sidewall of the insulating block 154 may be aligned with an outer sidewall of the back gate insulating layer 142. For example, the back gate insulating layer 142 may include a first sidewall in contact with the back gate line BG and a second sidewall opposite to the first sidewall, and the sidewall of the insulating block 154 may be aligned with the second sidewall of the back gate insulating layer 142.

The word line contact WLC may be disposed on the insulating block 154 in the interface area IA. The word line contact WLC may be disposed inside the word line contact hole WLCH extending into the interior of the insulating block 154 through the contact isolation insulating layer 162 and electrically connected to the word line WL. A portion of the sidewall of the word line contact WLC may be in contact with the insulating block 154, another portion of the sidewall of the word line contact WLC may be in contact with the contact isolation insulating layer 162, and the wiring layer 170 may be disposed on the upper surface of the word line contact WLC.

From a plan view, the word line contact WLC may include an odd word line contact WLC_L and an even word line contact WLC_R, and the odd word line contact WLC_L and the even word line contact WLC_R may be arranged to be offset from each other in the second horizontal direction Y.

In some example embodiments, as shown in FIG. 2, the word line contact WLC electrically connected to the second word line WL2 may be disposed in the interface area IA disposed on a first side of the cell array area MCA, and although not shown in FIG. 2, the word line contact WLC electrically connected to the first word line WL1 may be disposed in the interface area IA disposed on the second side opposite to the first side of the cell array area MCA. The odd word line contact WLC_L may be disposed on an odd second word line among the second word lines WL2 disposed in the interface area IA located on the first side of the cell array area MCA, and the even word line contact WLC_R may be disposed on the even second word line among the second word lines WL2 disposed in the interface area IA located on the first side of the cell array area MCA.

A distance hd2 from the end of the back gate line BG of the even word line contact WLC_R to an adjacent side of the even word line contact WLC_R may be different from a distance hd3 from the end of the back gate line BG of the odd word line contact WLC_L to an adjacent side of the odd word line contact WLC_L. For example, as shown in FIG. 2, the distance hd2 from the end of the back gate line BG of the even word line contact WLC_R to an adjacent side of the even word line contact WLC_R may be less than the distance hd3 from the end of the back gate line BG of the odd word line contact WLC_L to an adjacent side of the odd word line contact WLC_L. On the contrary, unlike what is shown in FIG. 2, the distance hd2 from the end of the back gate line BG of the even word line contact WLC_R to an adjacent side of the even word line contact WLC_R may be greater than the distance hd3 from the end of the back gate line BG of the odd word line contact WLC_L to an adjacent side of the odd word line contact WLC_L.

In other example embodiments, the word line contact WLC electrically connected to the second word line WL2 may be disposed in the interface area IA disposed on the first side of the cell array area MCA, the word line contact WLC electrically connected to the first word line WL1 may be disposed in the interface area IA disposed on the same first side of the cell array area MCA, and the word line contact WLC electrically connected to the first word line WL1 may be arranged to be offset in a second horizontal direction Y from the word line contact WLC electrically connected to the second word line WL2.

As the word line WL is disposed on both sidewalls of the insulating block 154 in the interface area IA, the end of the word line WL may be spaced apart from the end of the back gate line BG by a first horizontal distance hd1 in the second horizontal direction Y. In some example embodiments, the first horizontal separation distance hd1 may be greater than the width of the active semiconductor layer 140 and may be greater than the width of the dummy active semiconductor layer 140E. For example, the first horizontal separation distance hd1 may be greater than the width of the active semiconductor layer 140 in the second horizontal direction Y and may be greater than the width of the dummy active semiconductor layer 140E in the second horizontal direction Y.

As the word line contact WLC is disposed on the insulating block 154 in the interface area IA, the sidewall of the word line contact WLC may be spaced apart from the end of the back gate line BG by a second horizontal distance hd2 in the second horizontal direction Y. In other example embodiments, the second horizontal separation distance hd2 may be greater than the width of the active semiconductor layer 140.

In addition, as the word line WL is disposed on both sidewalls of the insulating block 154 in the interface area IA, a first gap d1 between two word lines WL disposed between two adjacent insulating blocks 154 in the interface area IA may be greater than a second gap d2 between two word lines WL disposed between two adjacent back gate lines BG in the interface area IA. In addition, the first gap d1 between two word lines WL disposed between two adjacent insulating blocks 154 in the interface area IA may be greater than a third gap d3 between two word lines WL disposed between two adjacent back gate lines BG in the cell array area MCA.

In some example embodiments, the insulating block 154 may be spaced apart from the back gate contact BGC in the second horizontal direction, and the word line contact WLC may be disposed to vertically overlap the word line WL on a portion of the insulating block 154. Accordingly, in a process of forming the word line contact WLC, a margin (e.g., misalignment margin of the word line contact WLC in the first horizontal direction X) for placing the word line contact WLC in the first horizontal direction X may be relatively large.

In addition, because the first gap d1 between two word lines WL disposed between two adjacent insulating blocks 154 in the interface area IA is greater than the second gap d2 between two word lines WL disposed between two adjacent back gate lines BG in the interface area IA, a margin for placing the word line contact WLC in the first horizontal direction X (e.g. misalignment margin of the word line contact WLC in the first horizontal direction X) may be relatively large in a process of forming the word line contact WLC.

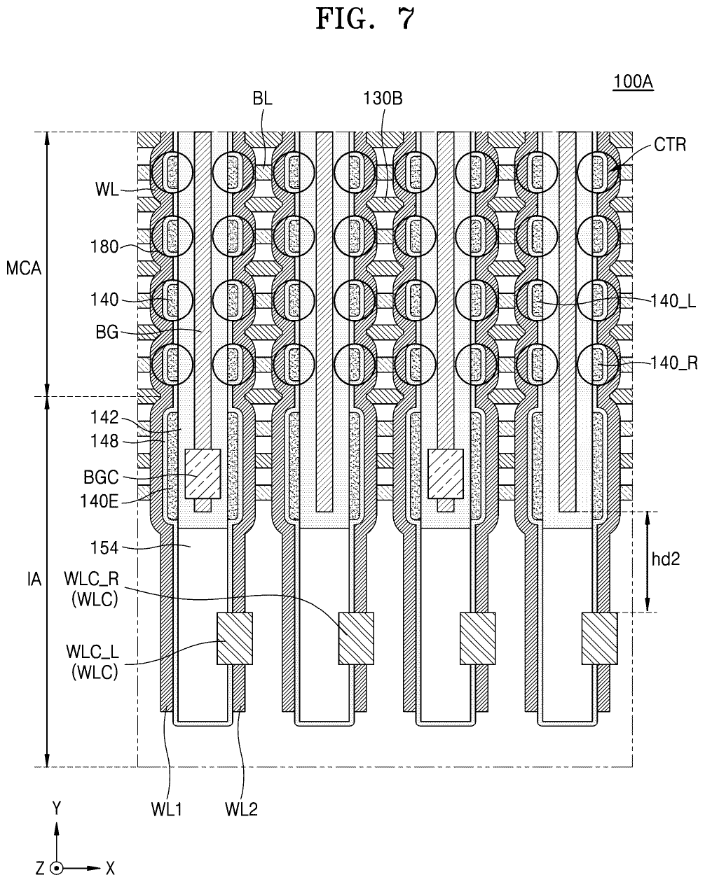

FIG. 7 is a plan view showing a semiconductor device 100A according to an example embodiment.

Referring to FIG. 7, from a plan view, word line contacts WLC may include odd word line contacts WLC_L and even word line contacts WLC_R, and the odd word line contact WLC_L and the even word line contact WLC_R may be aligned with each other in the second horizontal direction Y, for example, disposed at the same position in the second horizontal direction Y.

For example, as shown in FIG. 7, the word line contact WLC electrically connected to a second word line WL2 may be disposed in an interface area IA disposed on the first side of the cell array area MCA, and although not shown in FIG. 7, the word line contact WLC electrically connected to the first word line WL1 may be disposed in the interface area IA disposed on a second side opposite to the first side of the cell array area MCA.

The odd word line contact WLC_L may be disposed on the odd second word line among the second word lines WL2 disposed in the interface area IA disposed on the first side of the cell array area MCA, the even word line contact WLC_R may be disposed on the even second word line among the second word lines WL2 disposed in the interface area IA disposed on the first side of the cell array area MCA, and the distance hd2 from the end of the back gate line BG of the even word line contact WLC_R to an adjacent side of the even word line contact WLC_R may be equal to the distance from the end of the back gate line BG of the odd word line contact WLC_L to an adjacent side of the odd word line contact WLC_L.

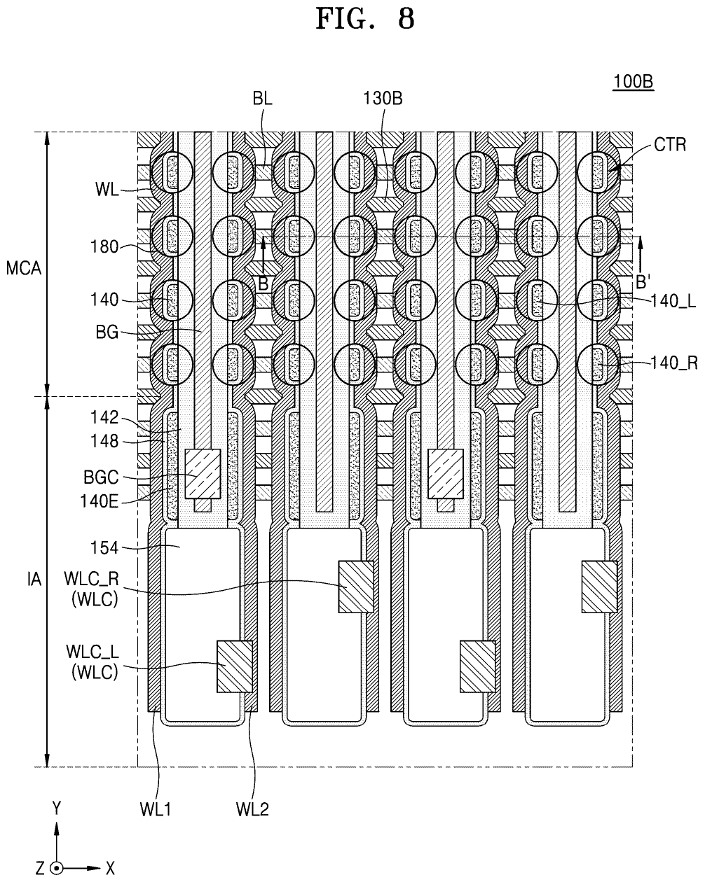

FIG. 8 is a plan view showing a semiconductor device 100B according to an example embodiment.

Referring to FIG. 8, the insulating block 154 may have a sidewall that protrudes outward from the outer sidewall of the back gate insulating layer 142. For example, the width of the insulating block 154 in the first horizontal direction X may be greater than the sum of the widths, in the first horizontal direction X, of the back gate line BG disposed between two adjacent dummy active semiconductor layers 140E and the back gate insulating layer 142 disposed on both sidewalls of the back gate line BG. For example, the sum of the widths, in the first horizontal direction X, of the back gate line BG disposed between two adjacent dummy active semiconductor layers 140E and the back gate insulating layer 142 disposed on both sidewalls of the back gate line BG may correspond to twice the sum of a first width of the back gate line BG in the first horizontal direction X and a second width of portions of the back gate insulating layer 142 in the first horizontal direction X.

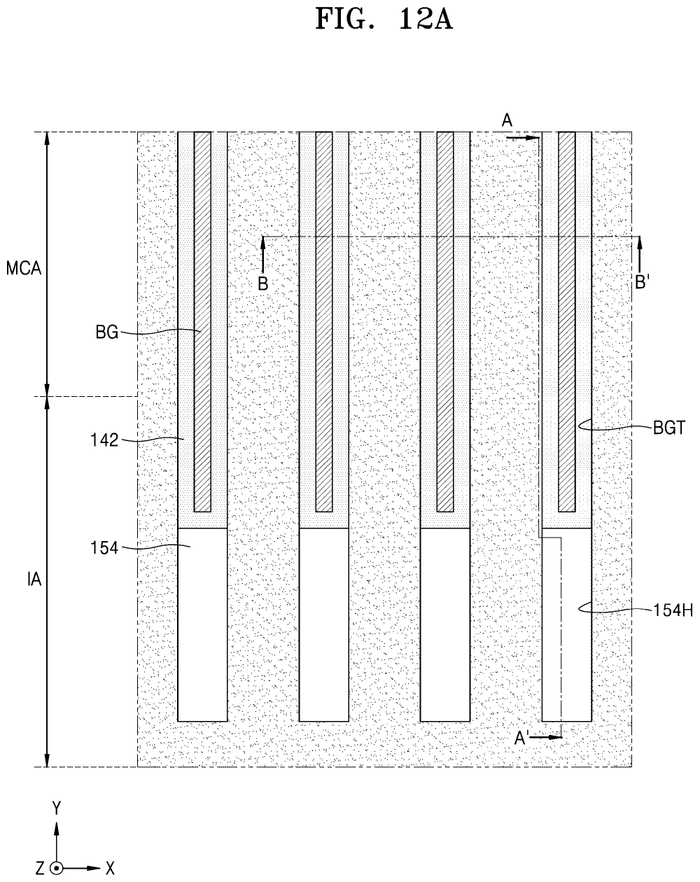

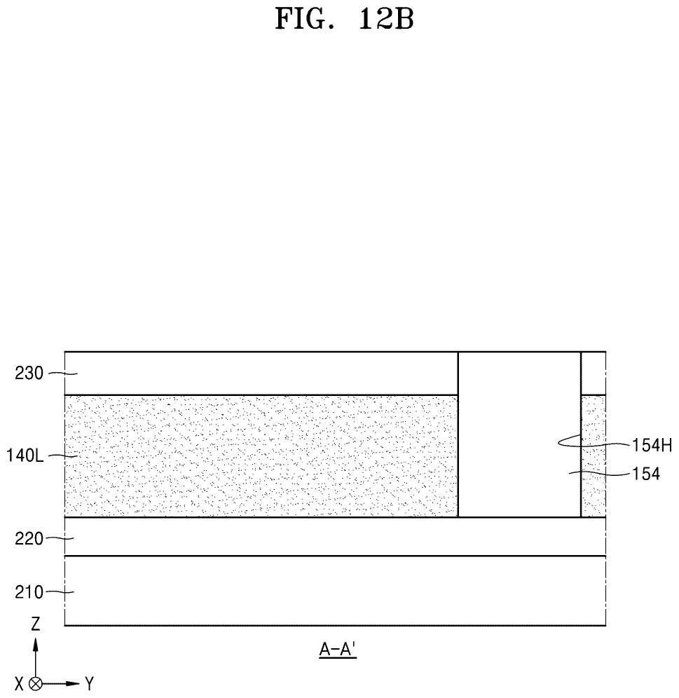

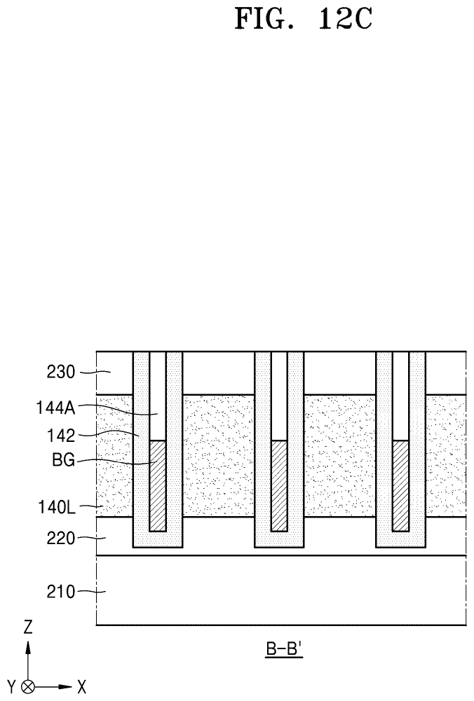

According to some example embodiments, the insulating block 154 may be formed before forming the back gate trench BGT (see FIG. 12A), or after forming the back gate trench BGT, using a mask pattern different from the mask pattern for forming the back gate trench BGT such that the width of the insulating block 154 in the first horizontal direction may be greater than the width in the first horizontal direction of portions of the back gate line BG disposed in the back gate trench BGT and portions of the back gate insulating layer 142 disposed on both sidewalls of the back gate line BG.

In other example embodiments, unlike shown in FIG. 8, the width of the insulating block 154 in the first horizontal direction X may be less than the width in the first horizontal direction X of the portion of the back gate line BG disposed in the back gate trench BGT and the portions of the back gate insulating layer 142 disposed on both sidewalls of the back gate line BG.

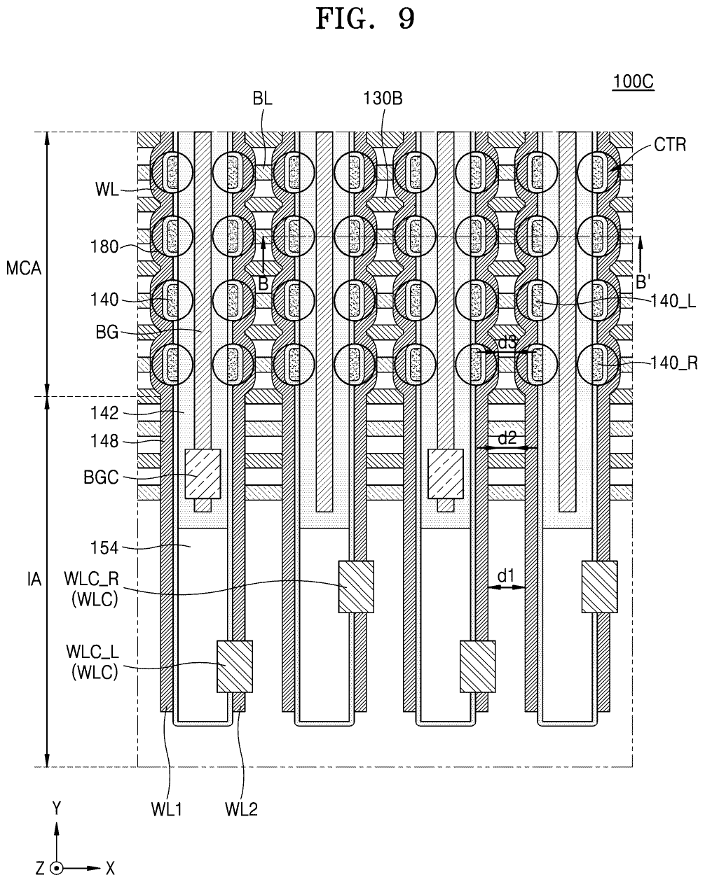

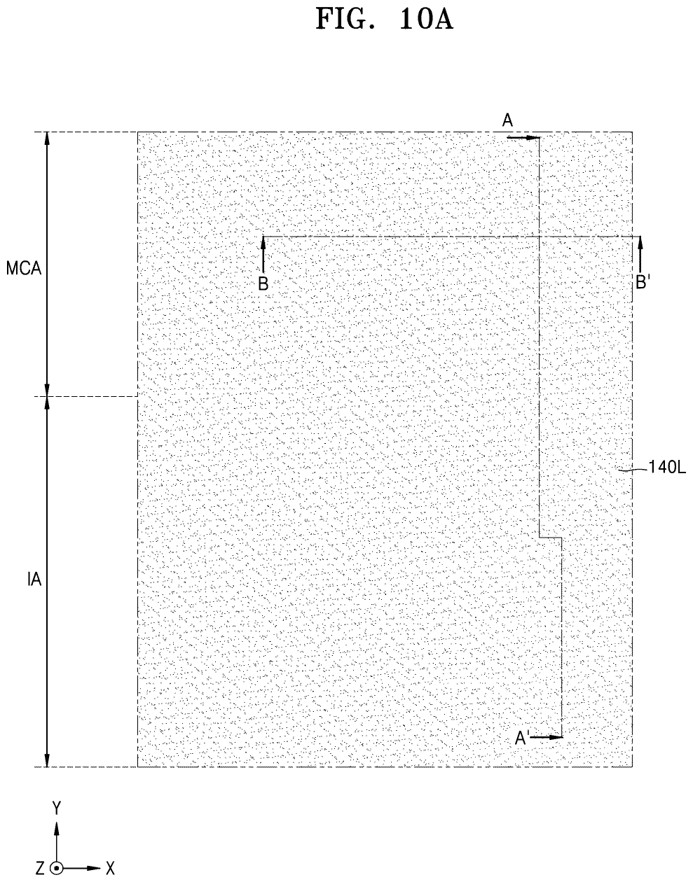

FIG. 9 is a plan view showing a semiconductor device 100C according to an example embodiment.

Referring to FIG. 9, the semiconductor device 100C according to an example embodiment may be similar to the semiconductor device 100 described with reference to FIGS. 1 to 6 except that the dummy active semiconductor layer 140E is omitted.

In some example embodiments, a back gate insulating layer 142 may be disposed on both sidewalls of the back gate line BG in the interface area IA, and a word line WL may extend on both sidewalls of the back gate line BG. For example, as the dummy active semiconductor layer 140E is omitted, a gate insulating layer 148 and the word line WL may be sequentially disposed on the sidewall of the back gate insulating layer 142 in the interface area IA. In some example embodiments, in the process of patterning an active semiconductor layer 140, the dummy active semiconductor layer 140E may be removed without being patterned.

For example, a first gap d1 between two word lines WL disposed between two adjacent insulating blocks 154 in the interface area IA may be equal to a second gap d2 between two word lines WL disposed between two adjacent back gate lines BG in the interface area IA, and the second gap d2 between two word lines WL disposed between two adjacent back gate lines BG in the interface area IA may be greater than a third gap d3 between two word lines WL disposed between two adjacent back gate lines BG in the cell array area MCA. In addition, the first gap d1 between two word lines WL disposed between two adjacent insulating blocks 154 in the interface area IA may be greater than the third gap d3 between two word lines WL disposed between two adjacent back gate lines BG in the cell array area MCA.

In some example embodiments, the insulating block 154 may be arranged to be spaced apart from the back gate contact BGC in the second horizontal direction Y, and the word line contact WLC may be arranged to vertically overlap the word line WL on a portion of the insulation block 154. Accordingly, in the process of forming the word line contact WLC, a margin for placing of the word line contact WLC in the first horizontal direction X (e.g., misalignment margin of the word line contact WLC in the first horizontal direction X) may be relatively large.

In some example embodiments, in the process of patterning the active semiconductor layer 140, the dummy active semiconductor layer 140E may be removed without being patterned.

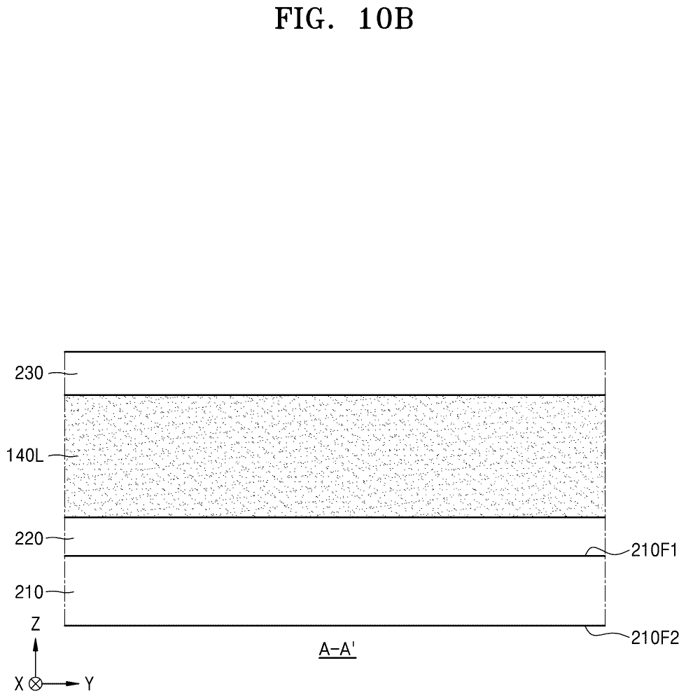

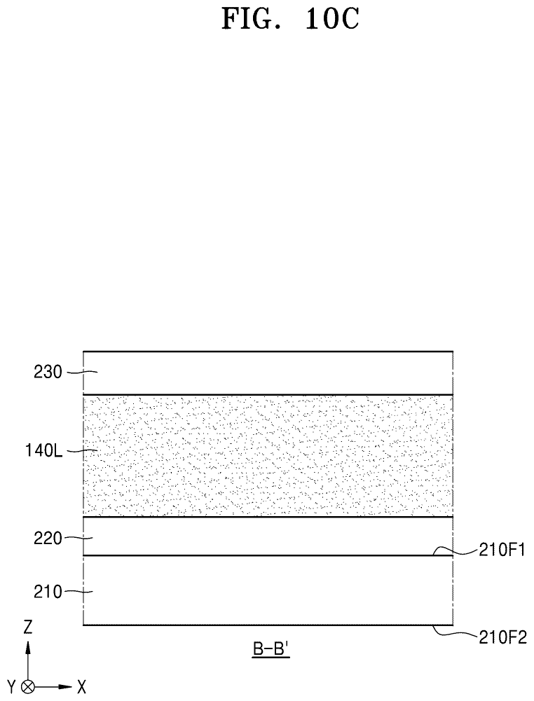

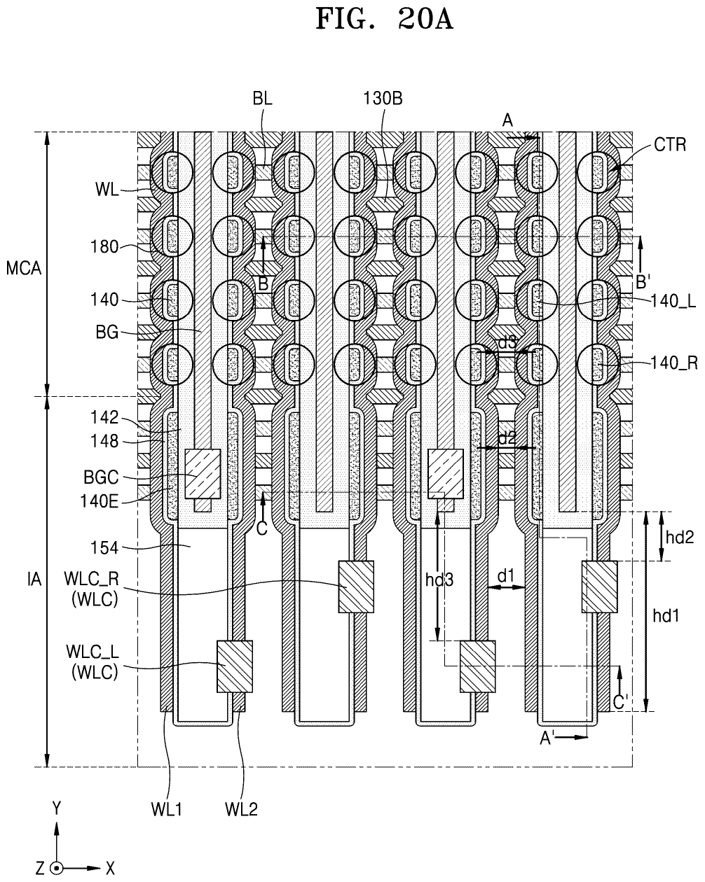

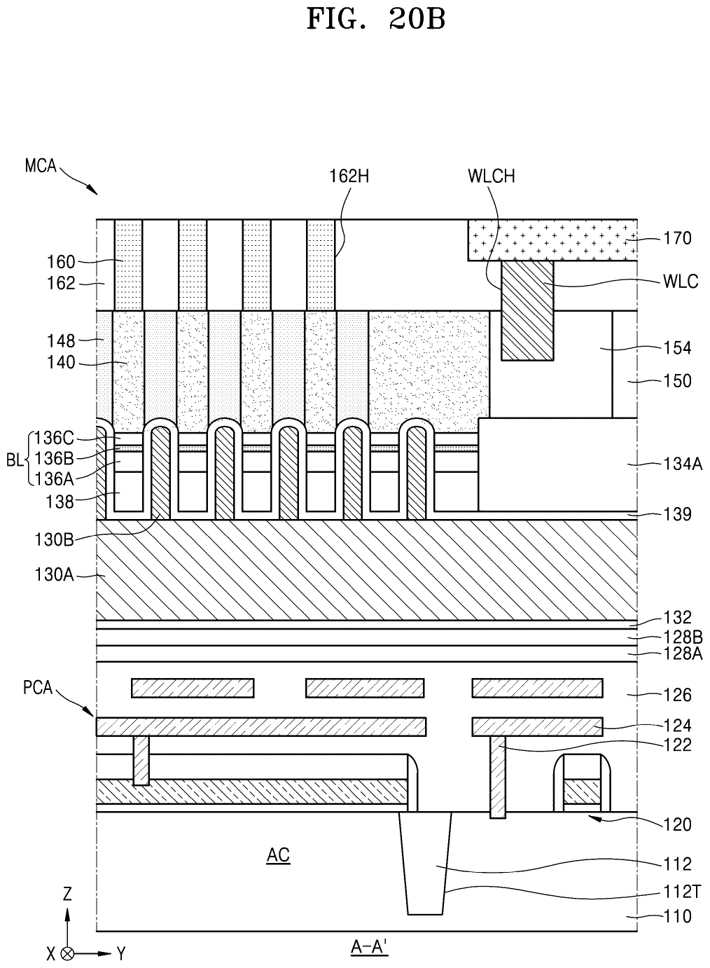

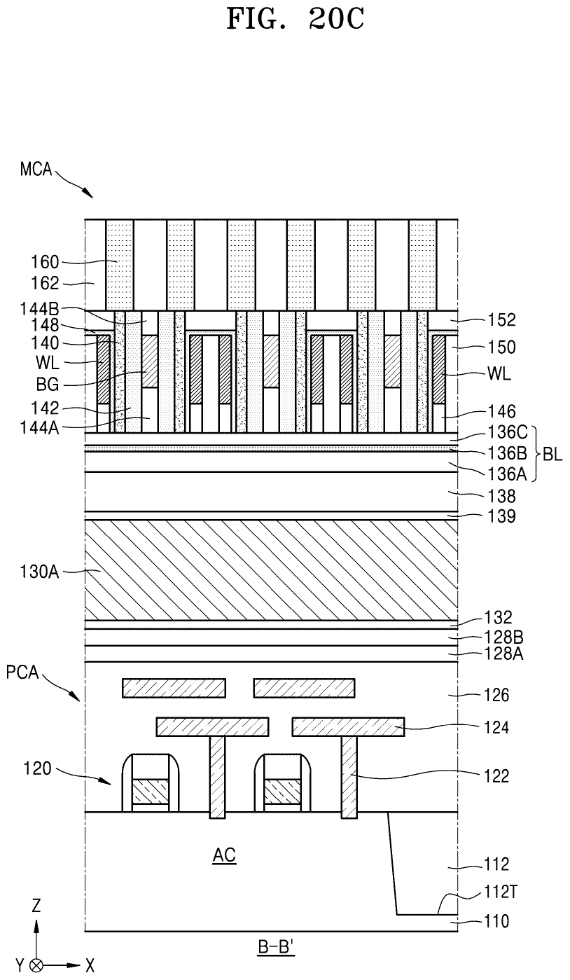

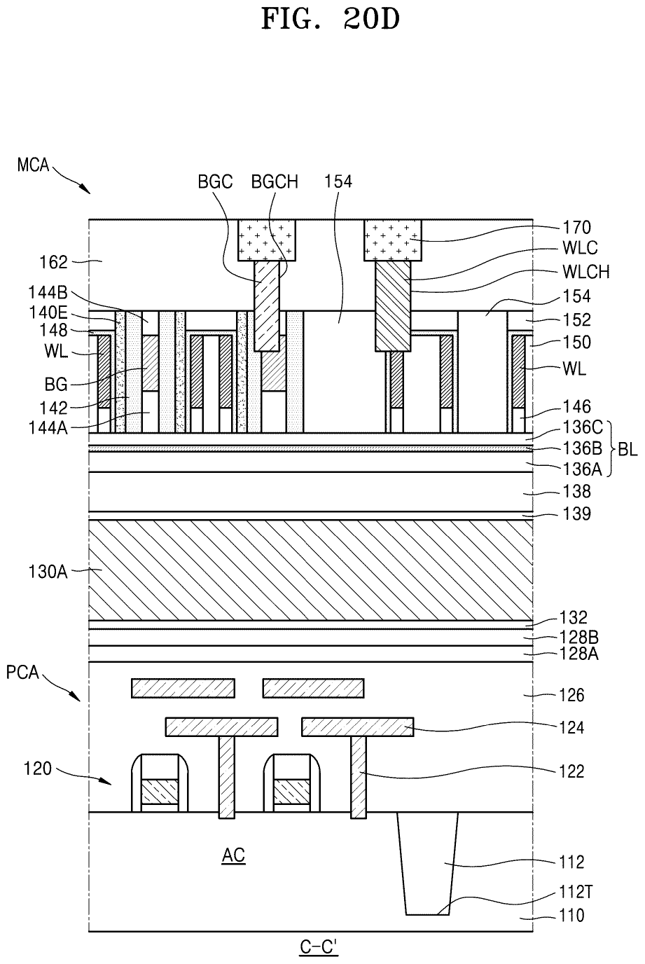

FIGS. 10A to 20D are schematic diagrams showing a method of manufacturing a semiconductor device 100, according to an example embodiment, wherein FIGS. 10A, 11A, 12A, 13A, 14A, 15A, 16A, 17A, and 20A are top views based on the process sequence, FIGS. 10B, 11B, 12B, 13B, 14B, 15B, 16B, 17B, 18A, 19A, and 20B are cross-sectional views taken along line A-A′ in FIG. 2 based on the process sequence, FIGS. 10C, 11C, 12C, 13C, 14C, 15C, 16C, 17C, 18B, 19B, and 20C are cross-sectional views taken along line B-B′ in FIG. 2 based on the process sequence, and FIG. 20D is a cross-sectional view taken along line C-C′ in FIG. 2 based on the process sequence.

Referring to FIGS. 10A to 10C, an intermediate insulating layer 220 and a semiconductor layer 140L may be formed on a first surface 210F1 of the sacrificial substrate 210 including the first surface 210F1 and a second surface 210F2. For example, the sacrificial substrate 210, the intermediate insulating layer 220, and the semiconductor layer 140L may be provided as a silicon-on-insulator (SOI)-type substrate.

In some example embodiments, the semiconductor layer 140L may include a semiconductor material, such as silicon, germanium, or silicon germanium. For example, the semiconductor layer 140L may include single crystal silicon. In some example embodiments, the semiconductor layer 140L may be silicon deposited as polysilicon and recrystallized by subsequent heat treatment.

A mask layer 230 may be formed on the semiconductor layer 140L. The mask layer 230 may include at least one of silicon oxide, silicon nitride, silicon oxynitride, and silicon carbide and, in some example embodiments, may be formed as a double layer structure of a silicon oxide layer and a silicon nitride layer.

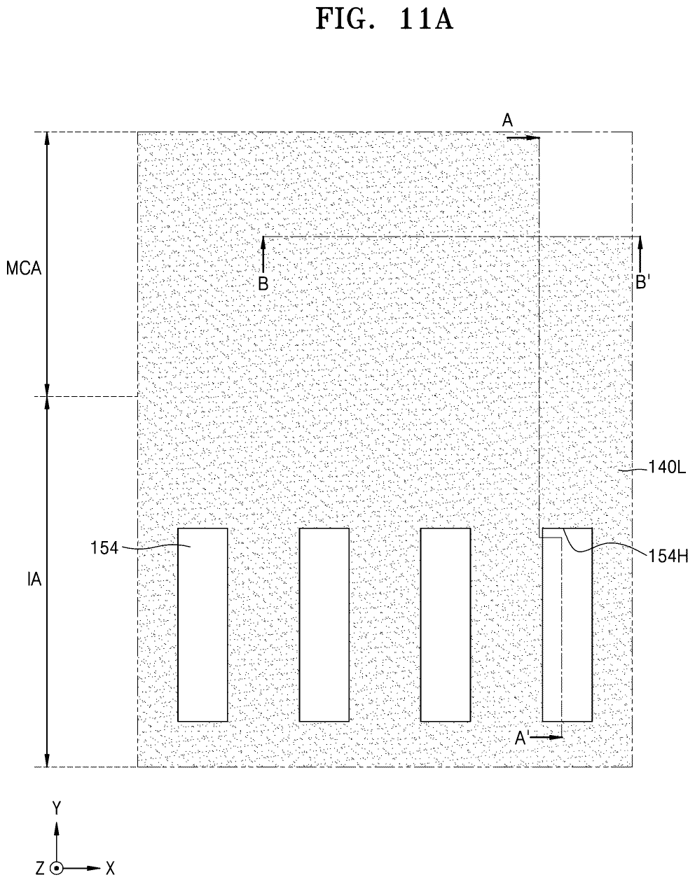

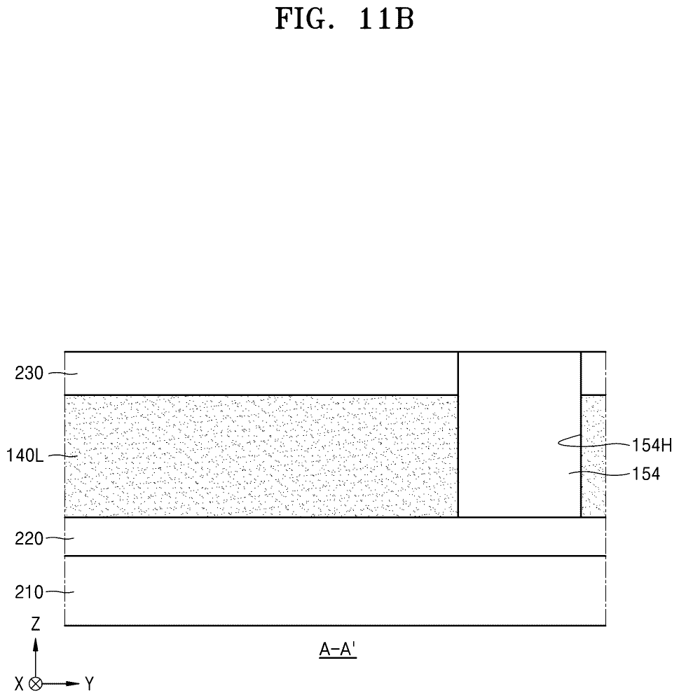

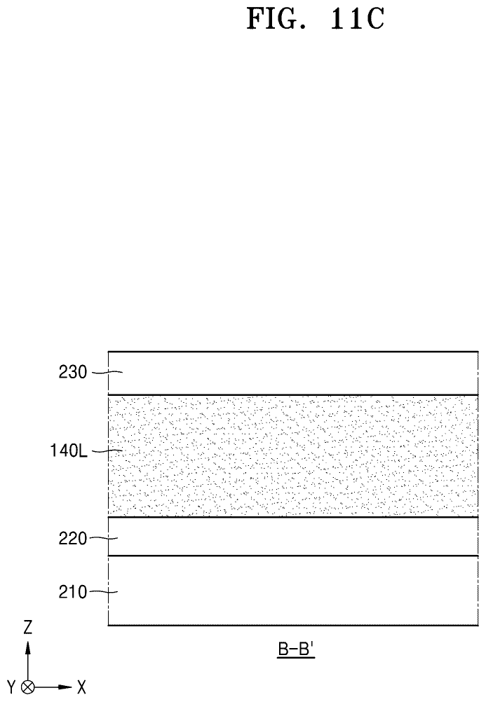

Referring to FIGS. 11A to 11C, a mask pattern may be formed on the mask layer 230, and the mask pattern may be used as an etch mask to remove a portion of the mask layer 230 and the semiconductor layer 140L from the interface area IA to form an opening 154H.

Thereafter, an insulating block 154 may be formed using an insulating material within the opening 154H. The insulating block 154 may have an upper surface disposed at the same level as the upper surface of the mask layer 230.

Referring to FIGS. 12A to 12C, a back gate trench BGT may be formed by forming a mask pattern on the mask layer 230 and using the mask pattern as an etch mask to remove a portion of the mask layer 230 and semiconductor layer 140L from the cell array area MCA.

In some example embodiments, the back gate trench BGT may be formed in a line shape extending in the second horizontal direction Y, and an end of the back gate trench BGT may be connected to or contact the opening 154H or the insulating block 154. For example, a sidewall of the back gate trench BGT may be arranged to be aligned with a sidewall of the opening 154H.

Thereafter, a back gate insulating layer 142 may be formed in the back gate trench BGT, and a back gate line BG may be formed on the back gate insulating layer 142 in the back gate trench BGT.

Then, a portion of the back gate line BG disposed above the back gate trench BGT may be removed, and a first back gate capping layer 144A may be formed on the back gate line BG using an insulating material. In some example embodiments, the first back gate capping layer 144A may include silicon nitride.

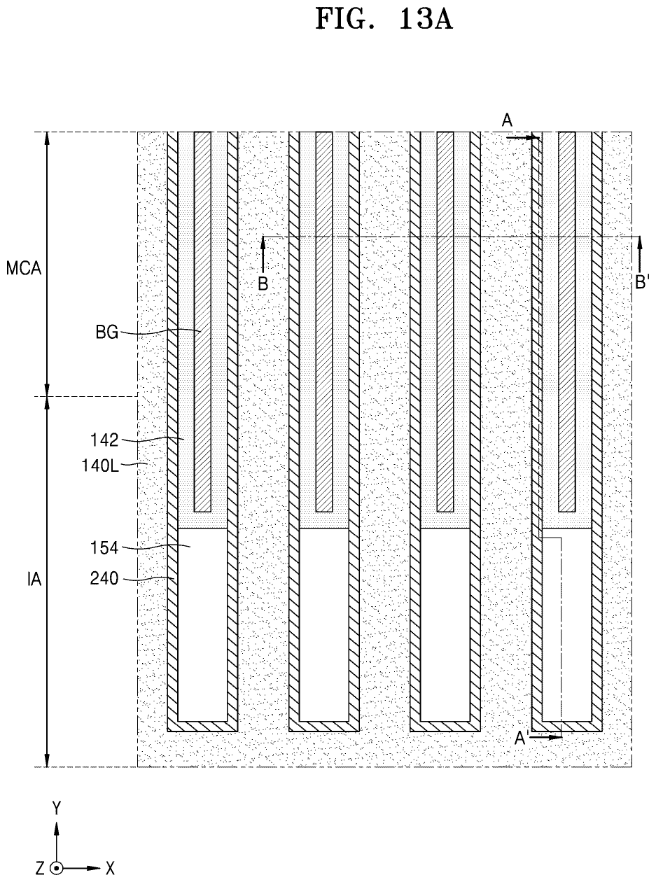

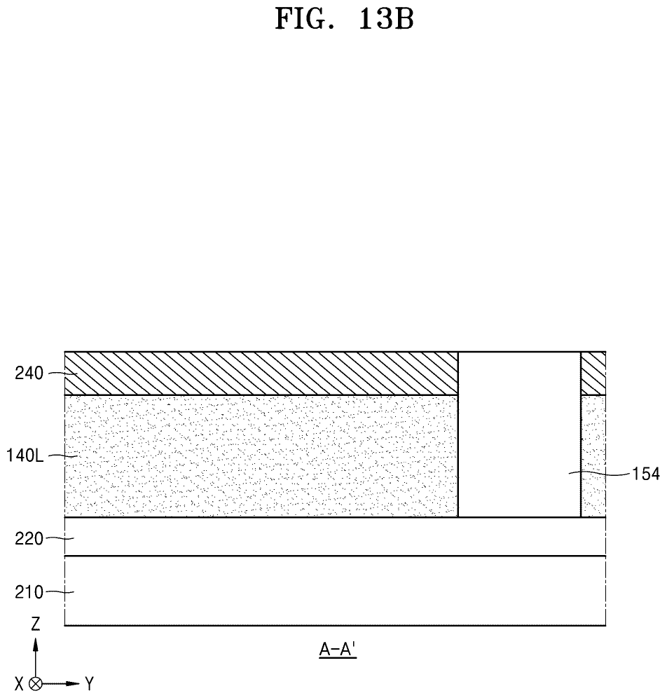

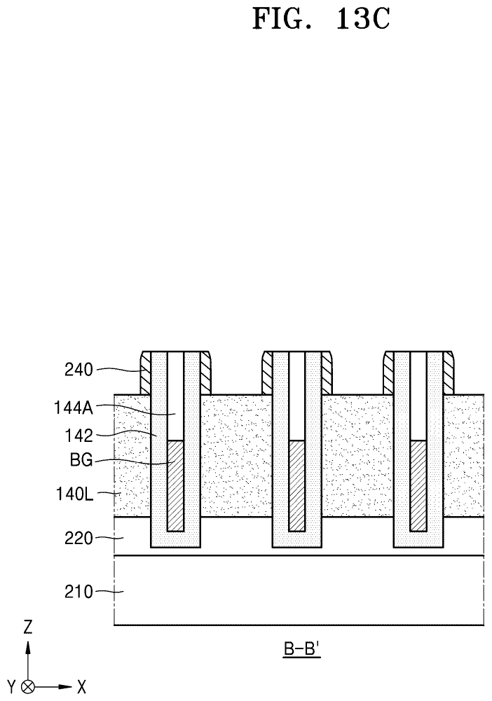

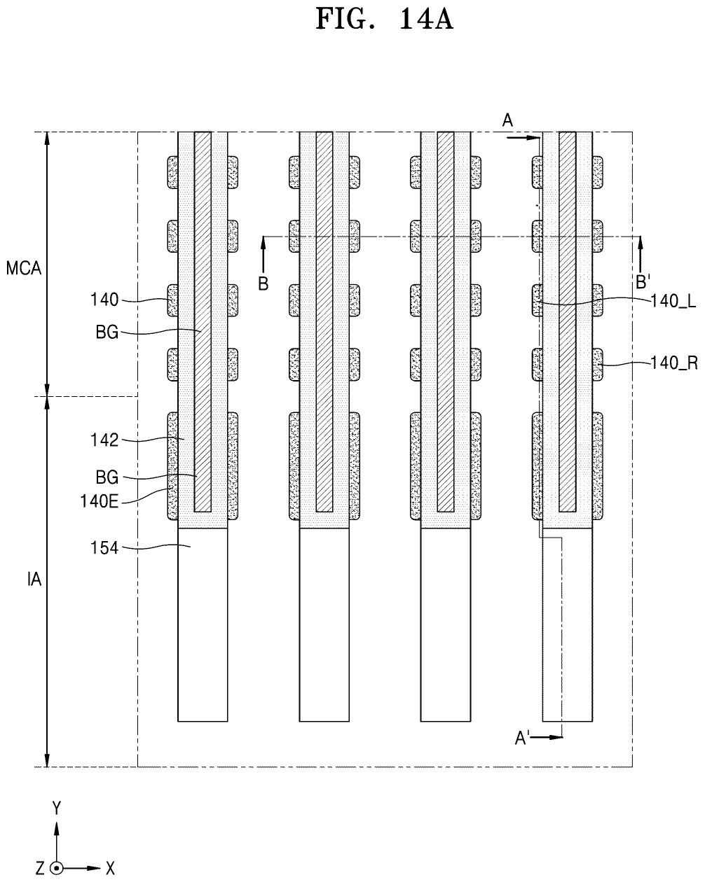

Referring to FIGS. 13A to 13C, the mask layer 230 may be removed and an upper surface of the semiconductor layer 140L may be exposed.

Thereafter, a spacer mask 240 may be formed on the sidewall of the back gate insulating layer 142. In some example embodiments, the spacer mask 240 may be formed in a self-aligned manner on the sidewall of the back gate insulating layer 142 on the upper surface of the semiconductor layer 140L. For example, an insulating layer may be formed on the upper surface of the semiconductor layer 140L, and an anisotropic etching process may be performed on the insulating layer to form a spacer mask 240 on the sidewall of the back gate trench BGT. From a plan view, the spacer mask 240 may be arranged to surround the back gate line BG and the back gate insulating layer 142 and may also be arranged to surround the insulating block 154.

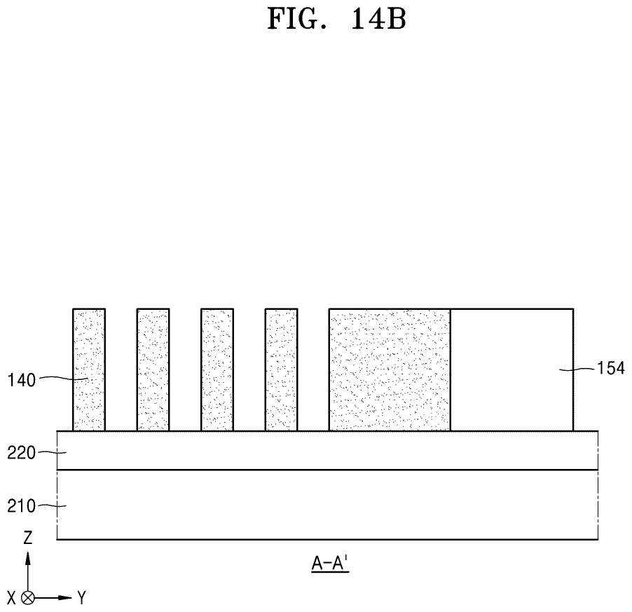

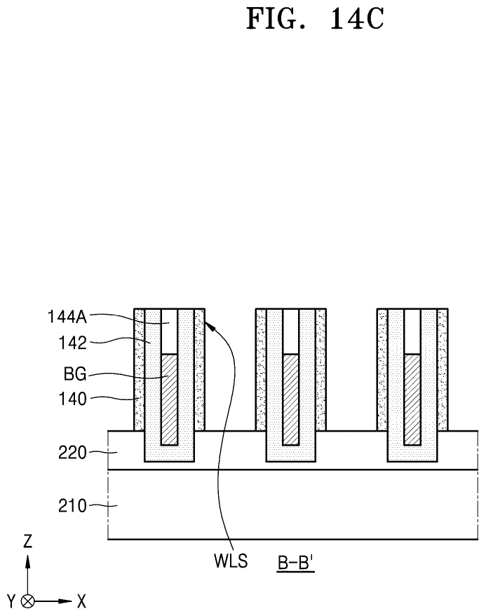

Referring to FIGS. 14A to 14C, the semiconductor layer 140L (refer to FIG. 13B) may be patterned using the spacer mask 240 as an etch mask to form an active semiconductor layer 140 on the cell array area MCA and a dummy active semiconductor layer 140E on the interface area IA.

In some example embodiments, the semiconductor layer 140L is etched using the spacer mask 240 as an etch mask, leaving a semiconductor layer 140L under the spacer mask 240 at a position that vertically overlaps the spacer mask 240, and then an additional mask pattern in the shape of a line pattern extending in the first horizontal direction X may be formed on the cell array area MCA, and portions of the semiconductor layer 140L not covered by the additional mask pattern may be removed. Thus, portions of the semiconductor layer 140L arranged to be spaced apart in the second horizontal direction Y may remain on the cell array area MCA, and portions of the semiconductor layer 140L may remain on the interface area IA.

Here, the portions of the semiconductor layer 140L arranged to be spaced apart in the second horizontal direction Y on the cell array area MCA may be referred to as a plurality of active semiconductor layers 140, and the portion of the semiconductor layer 140L remaining on the interface area IA may be referred to as the dummy active semiconductor layer 140E. The active semiconductor layer 140 and the dummy active semiconductor layer 140E may be formed by patterning the semiconductor layer 140L and may include, for example, silicon.

After the semiconductor layer 140L is removed, an upper surface of the intermediate insulating layer 220 may be exposed. The space between two adjacent back gate trenches BGT (for example, the space between a back gate line BG and an adjacent back gate line BG) may be referred to as a word line space WLS.

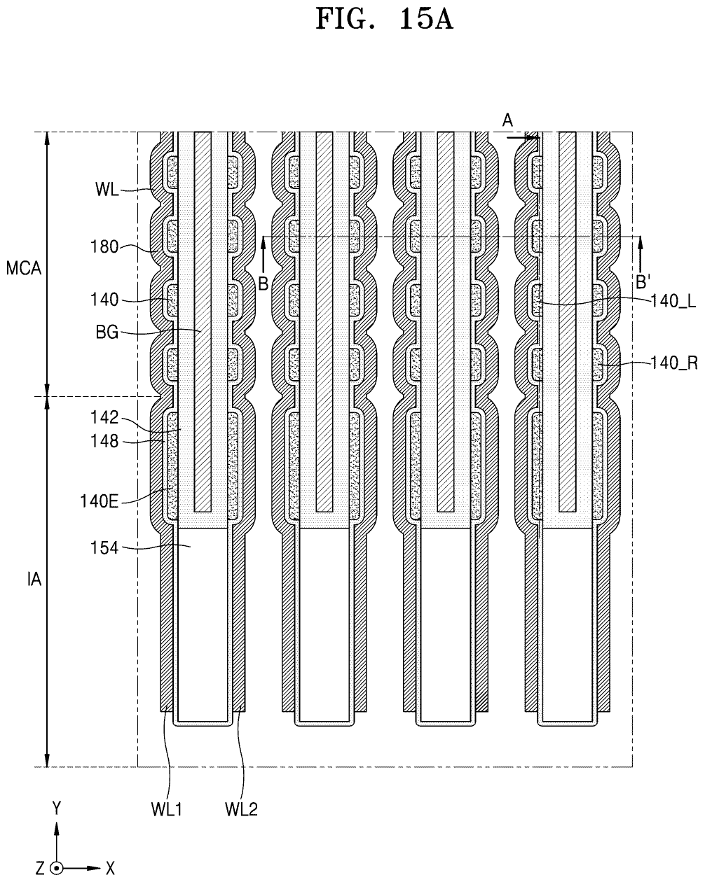

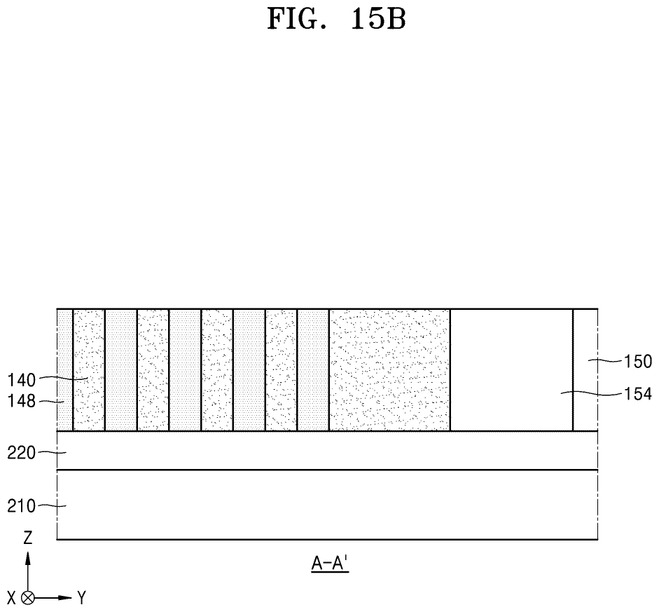

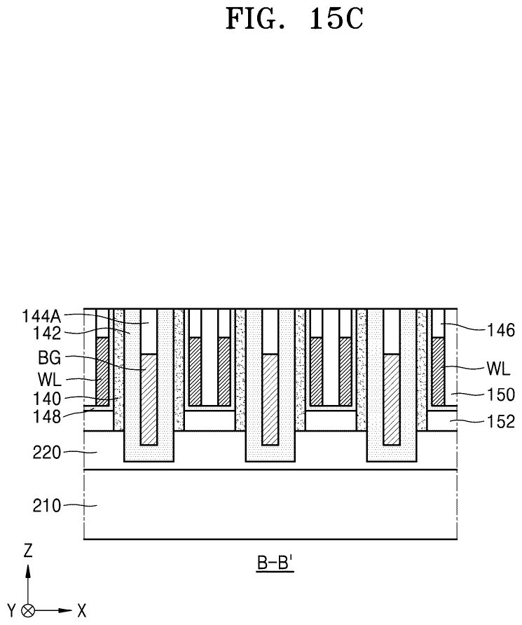

Referring to FIGS. 15A to 15C, a second insulating layer 152 may be formed at the bottom of the word line space WLS.

A gate insulating layer 148 may be formed on an inner wall of the word line space WLS. The gate insulating layer 148 may be formed on the sidewall of the word line space WLS and the upper surface of the second insulating layer 152, and may have a U-shaped vertical cross-section.

Thereafter, a word line WL may be formed on the inner wall of the word line space WLS. In some example embodiments, the word line WL may have a rectangular or bar-shaped vertical cross-section disposed on a sidewall of the gate insulating layer 148 and may extend in the second horizontal direction Y on the inner wall of the word line space WLS.

In the interface area IA, the word line WL may be disposed to surround the insulating block 154 and may be disposed on a sidewall of the insulating block 154.

Afterwards, a buried insulating layer 150 may be formed on the word line WL. In the cell array area, the buried insulating layer 150 may extend in the second horizontal direction Y inside the word line space WLS, and in the interface area, the sidewalls of the insulating block 154 in the interface area may be covered by a buried insulating layer 150.

Afterwards, the upper side of the word line WL may be removed through a recess process, and a word line capping layer 146 may be formed in the space where the word line WL has been removed. The upper surface of the word line capping layer 146, the top surface of the gate insulating layer 148, the top surface of the active semiconductor layer 140, the top surface of the back gate insulating layer 142, the first back gate capping layer 144A, and the top surface of the buried insulating layer 150 may be disposed at the same level.

In some example embodiments, a back gate pad electrically connected to the back gate line BG may be formed in the interface area IA. The back gate pad may be formed by removing a portion of the back gate line BG and a portion of the back gate insulating layer 142 disposed on both sides of the portion of the back gate line BG to form a back gate pad hole and filling the back gate pad hole with a conductive material. The back gate pad may have a width greater than the back gate line BG.

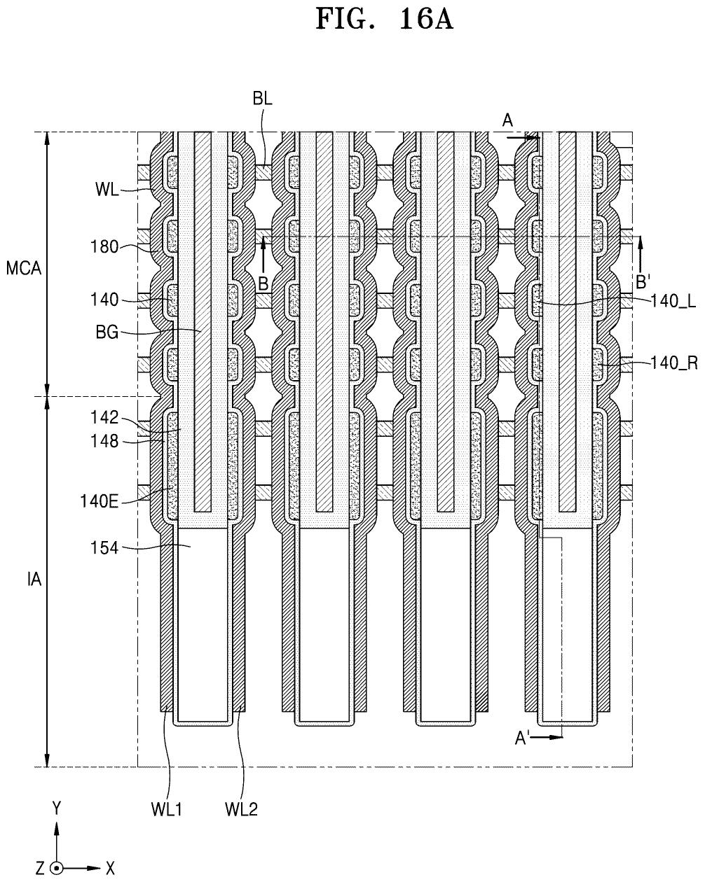

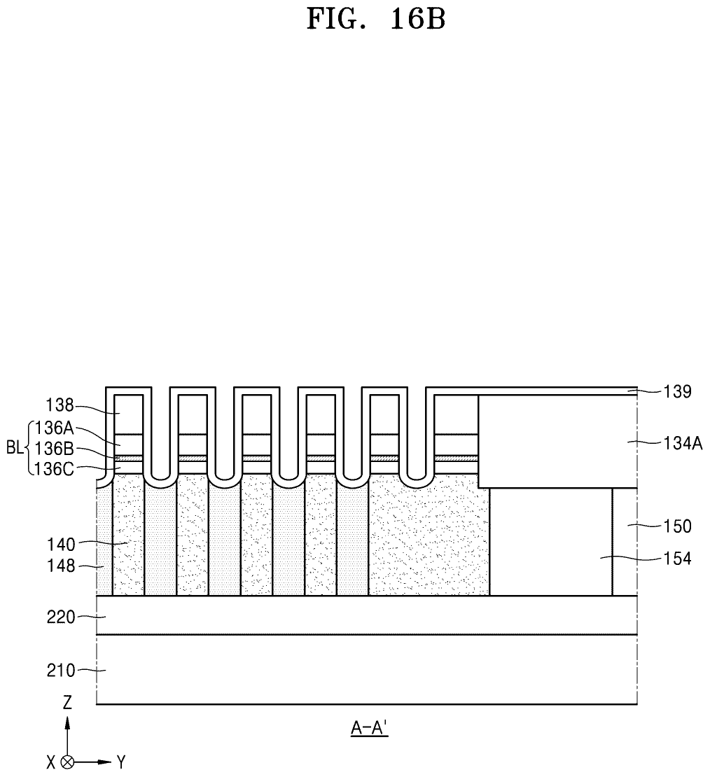

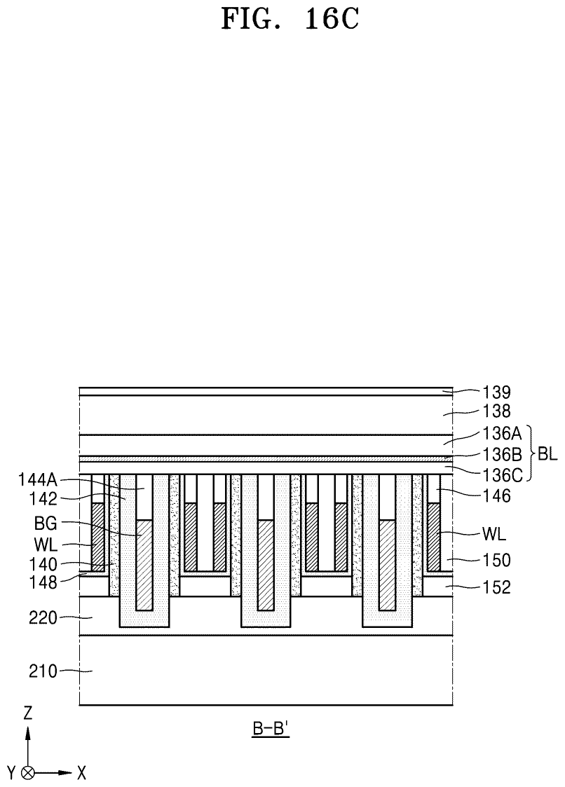

Referring to FIGS. 16A to 16C, a conductive stack for a bit line may be formed on the exposed upper surface of the active semiconductor layer 140, and a bit line BL extending in the first horizontal direction X may be formed by patterning the bit line conductive stack.

In some example embodiments, the bit line BL may include a first bit line conductive layer 136A, a second bit line conductive layer 136B, and a third bit line conductive layer 136C. In some example embodiments, the first bit line conductive layer 136A may include a metal material (e.g., tungsten or ruthenium), the second bit line conductive layer 136B may include titanium nitride or metal silicide, and the third bit line conductive layer 136C may include polysilicon.

Thereafter, an insulating liner 139 may be formed conformally on the top surface and sidewalls of the bit line BL.

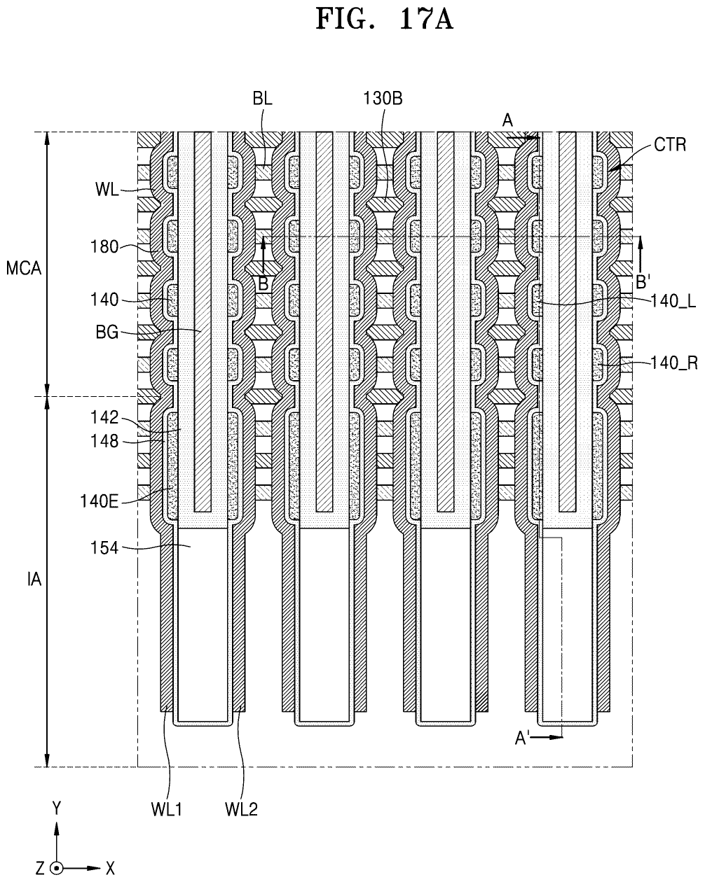

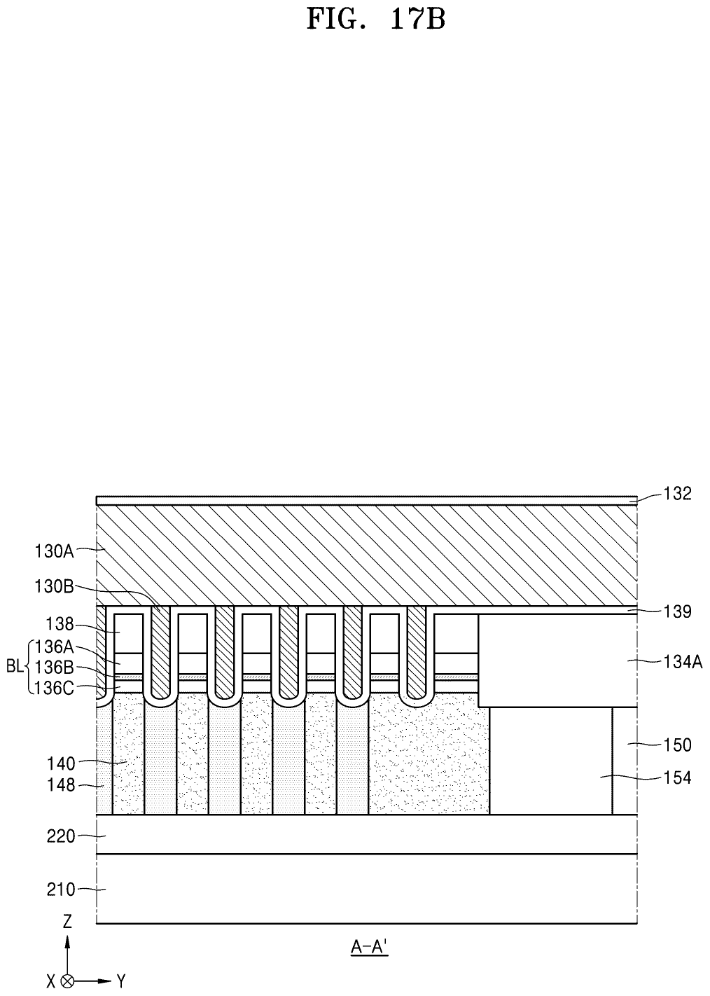

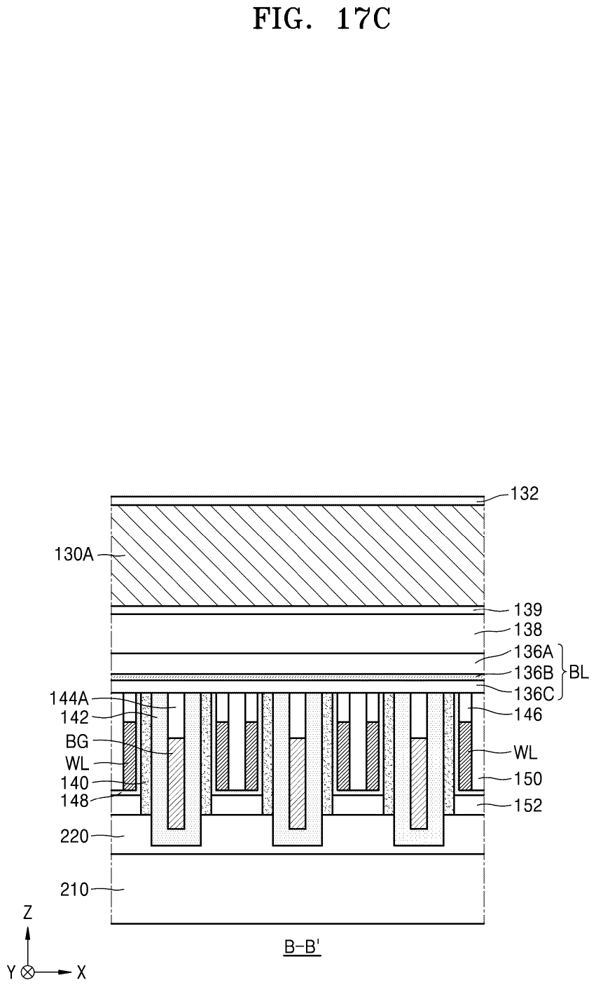

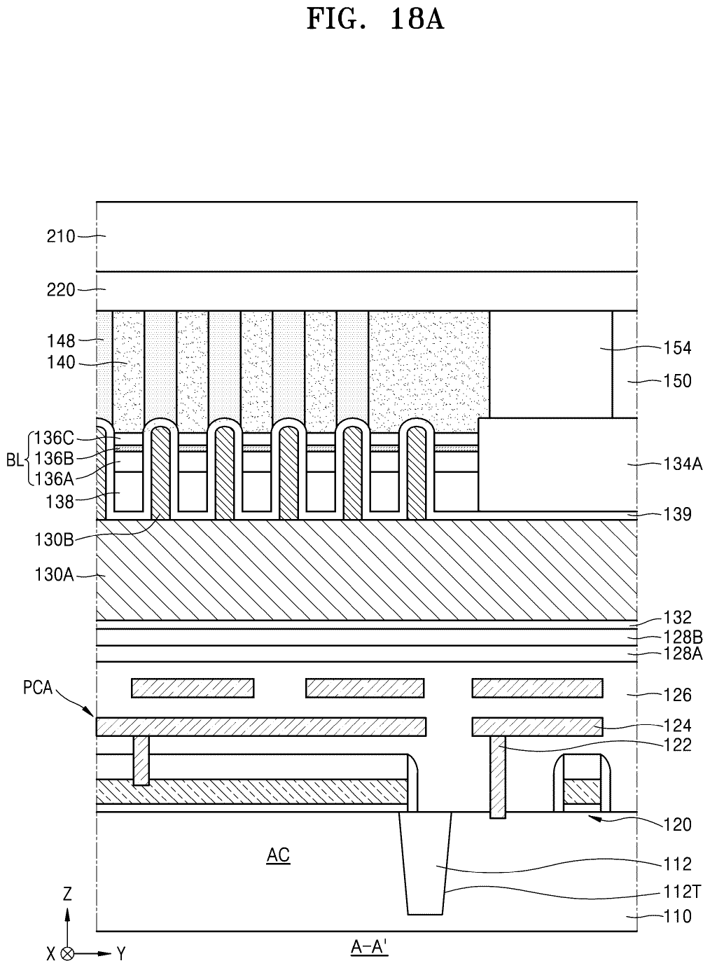

Referring to FIGS. 17A to 17C, a second shield layer 130B may be formed in the space between the plurality of bit lines BL on the insulating liner 139. Afterwards, a first shield layer 130A may be formed on the second shield layer 130B.

In some example embodiments, the second shield layer 130B may include Ti, TiN, Ta, TaN, Mo, MoN, Ru, W, WN, Co, TiSiN, WSiN, polysilicon, or a combination thereof. The first shield layer 130A may include Ti, TiN, Ta, TaN, Mo, MoN, Ru, W, WN, Co, TiSiN, WSiN, polysilicon, or a combination thereof. In some example embodiments, the second shield layer 130B is formed in the space between the plurality of bit lines BL, and then the second shield layer 130B may be planarized by performing a planarization process on the upper of the second shield layer 130B, and the first shield layer 130A may be formed on the second shield layer 130B. In some example embodiments, the second shield layer 130B may be formed in the same process as the first shield layer 130A, and accordingly, the second shield layer 130B may be integrally connected to the first shield layer 130A.

Afterwards, a first insulating layer 132 may be formed on the first shield layer 130A.

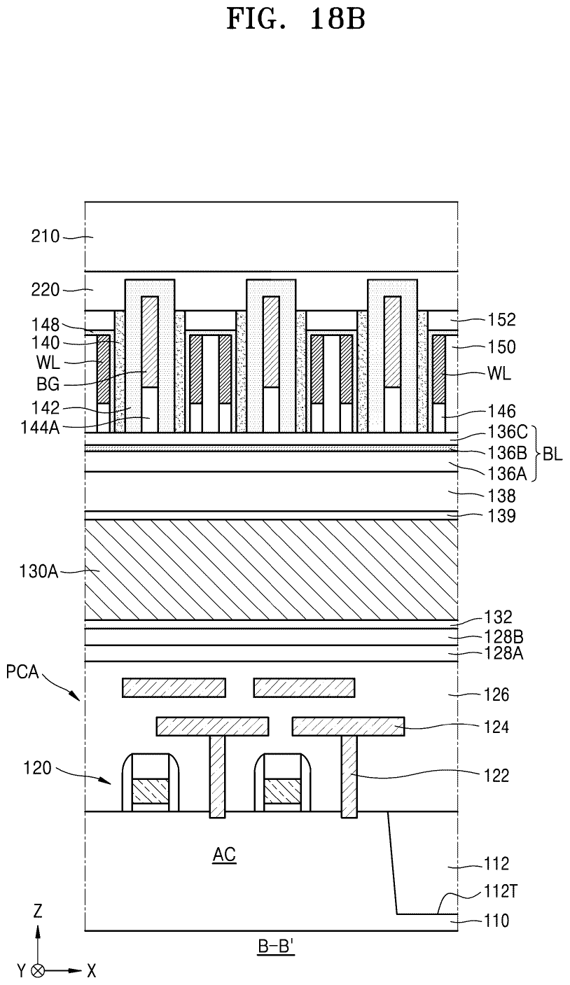

Referring to FIGS. 18A and 18B, a peripheral circuit area PCA may be prepared.

The peripheral circuit area PCA may be prepared by forming a device isolation film 112 and an active area AC on the substrate 110, and forming a peripheral circuit transistor 120, a peripheral circuit contact 122, a peripheral circuit wiring layer 124, and an interlayer insulating film 126 on the substrate 110.

Thereafter, an intermediate insulating layer 220 may be disposed on the structure of FIGS. 18A-18C and a sacrificial substrate 210 may be disposed on the intermediate insulating layer 220 to form an intermediate cell array area structure. The intermediate cell array area structure may be attached to the peripheral circuit area PCA so that the first shield layer 130A is disposed on the peripheral circuit area PCA.

In some example embodiments, the intermediate cell array area structure and the peripheral circuit area PCA may be attached using a wafer bonding method, such as an oxide bonding method or a metal-oxide hybrid bonding method. For example, a first bonding insulating layer 128A may be formed on the top surface of the peripheral circuit area PCA (e.g., the upper surface of the interlayer insulating film 126), a second bonding insulating layer 128B may be formed on the top surface of the intermediate cell array structure (e.g., the top surface of the first insulating layer 132), and the sacrificial substrate 210 and the peripheral circuit area PCA may be attached to each other such that the first bonding insulating layer 128A and the second bonding insulating layer 128B are in contact with each other.

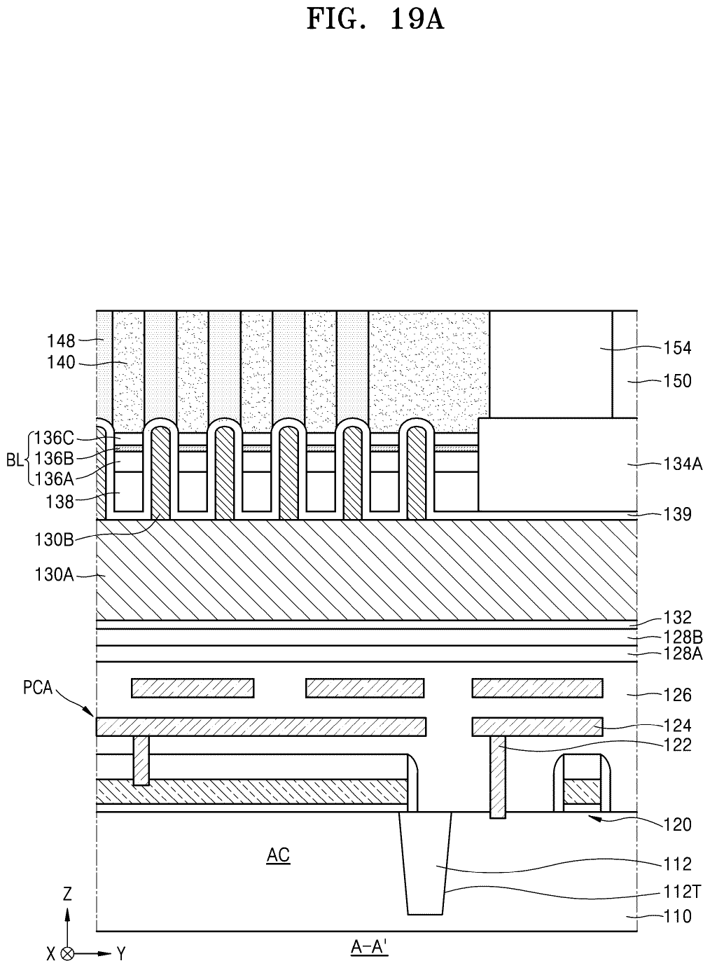

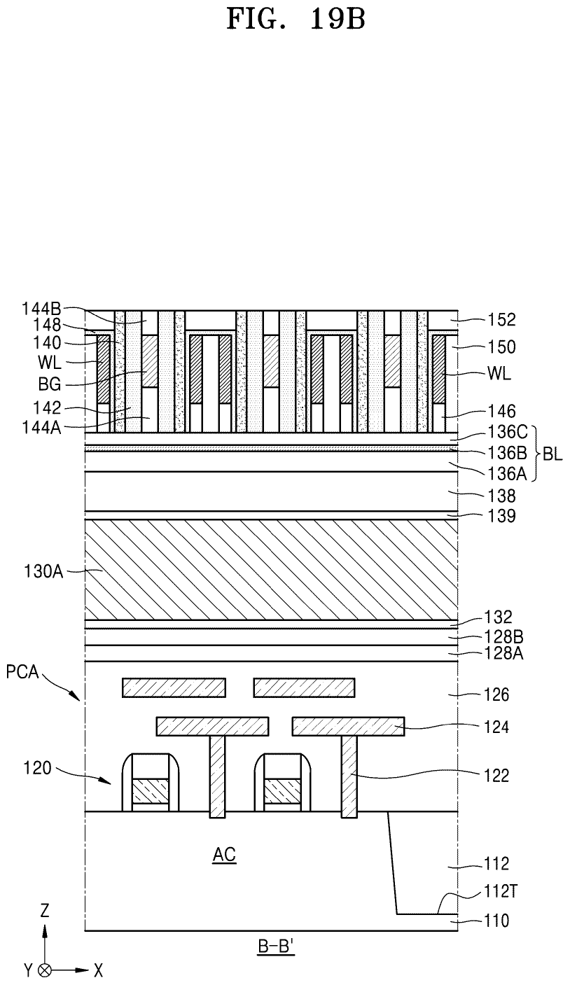

Referring to FIGS. 19A and 19B, the sacrificial substrate 210 may be removed.

In some example embodiments, the removal process of the sacrificial substrate 210 may be performed by grinding, wet etching, or a combination thereof. The sacrificial substrate 210 may be removed, and then the intermediate insulating layer 220 may be removed, and the active semiconductor layer 140 and the back gate insulating layer 142 may be exposed.

Referring to FIGS. 20A to 20D, a portion of the back gate insulating layer 142 may be removed and the back gate line BG may be exposed. Afterwards, a portion of the upper side of the back gate line BG may be removed, and a second back gate capping layer 144B may be formed on the upper surface of the back gate line BG.

Thereafter, a storage insulating layer 162 may be formed on the active semiconductor layer 140 and the word line WL, and a portion of the storage insulating layer 162 may be removed to form an opening 162H exposing an upper surface of the active semiconductor layer 140. Afterwards, a storage contact 160 may be formed within the opening 162H. The storage contact 160 may include Ti, TiN, Ta, TaN, Mo, MoN, Ru, W, WN, Co, TiSiN, WSiN, polysilicon, or silicide materials thereof.

In some example embodiments, before forming the storage contact 160, source/drain areas may be formed by implanting impurity ions on the exposed upper side of the active semiconductor layer 140.

Afterwards, a portion of the storage insulating layer 162 and the insulating block 154 may be removed from the interface area IA to form a word line contact hole WLCH, and a portion of the storage insulating layer 162 and the second back gate capping layer 144B may be removed to form the back gate contact hole BGCH. Thereafter, a word line contact WLC may be formed within the word line contact hole WLCH and a back gate contact BGC may be formed within the back gate contact hole BGCH.

In some example embodiments, the process of forming the word line contact hole WLCH and the process of forming the back gate contact hole BGCH may be performed separately. In some example embodiments, the process of forming the word line contact hole WLCH and the process of forming the back gate contact hole BGCH may be performed simultaneously.

In the process of forming the word line contact hole WLCH, because the word line contact hole WLCH is arranged to be spaced apart from the back gate line BG in the second horizontal direction Y, a misalignment margin of the word line contact hole WLCH in the second horizontal direction Y may be relatively large. In addition, because the word line contact hole WLCH is arranged to vertically overlap the insulating block 154, the misalignment margin of the word line contact hole WLCH in the first horizontal direction X may be relatively large. In addition, because the separation distance (e.g., first distance d1 in FIG. 2) between word lines between two adjacent insulating blocks 154 in the interface area IA is greater than the separation distance (e.g., second distance d2 in FIG. 2) between word lines WL disposed between two adjacent dummy active semiconductor layers 140E, the misalignment margin of the word line contact hole WLCH in the first horizontal direction X may be relatively large.

Afterwards, a wiring layer 170 that is electrically connected to the word line contact WLC and the back gate contact BGC may be formed.

Referring again to FIG. 3, the storage node 180 may be formed on the storage contact 160.

The semiconductor device 100 may be completed by performing the above-described process.

According to some example embodiments, an insulating block 154 may be disposed in the interface area IA at a position overlapping a plurality of back gate lines BG in the second horizontal direction Y, and a word line contact WLC may be formed on the insulating block 154 and the word line WL. Accordingly, in a process of forming the word line contact, a margin for placing the word line contact WLC in the first horizontal direction (e.g., misalignment margin of the word line contact WLC in the first horizontal direction X) may be relatively large.

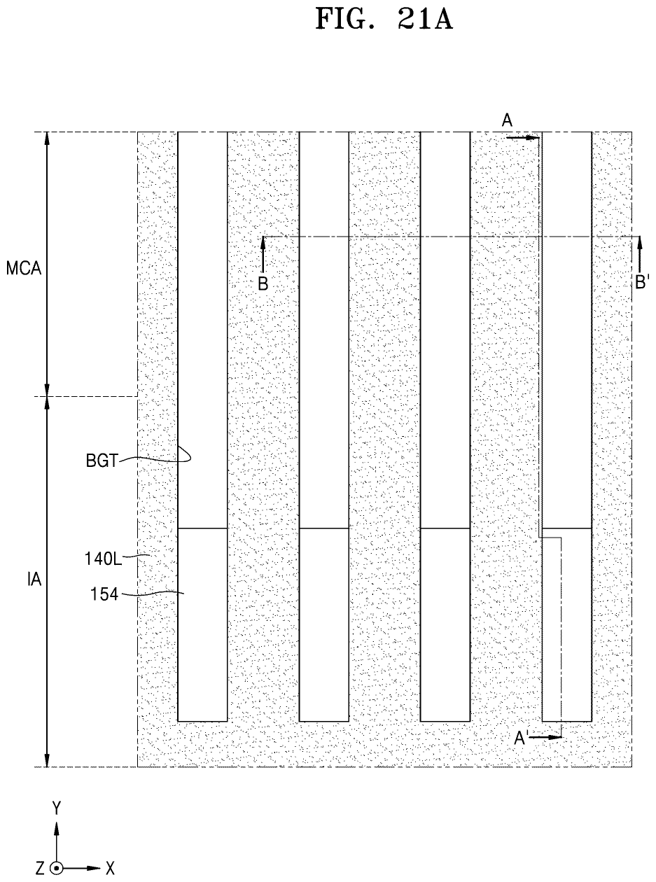

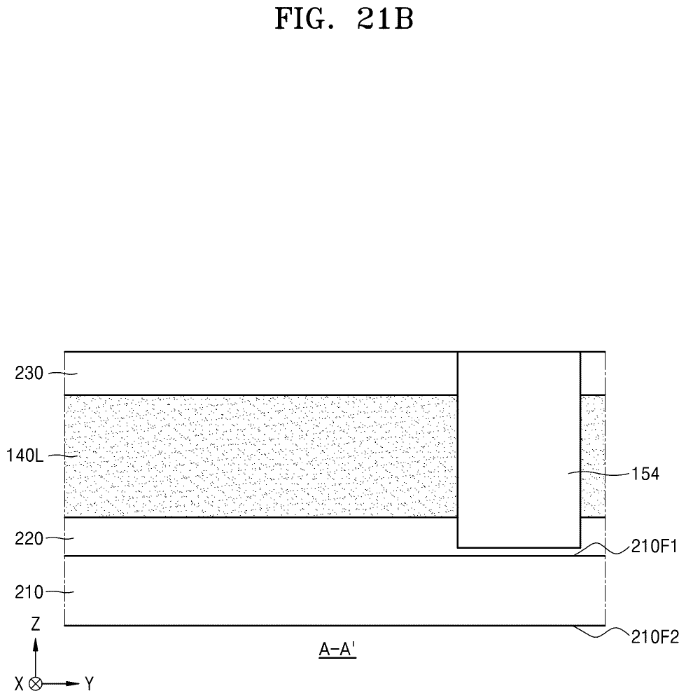

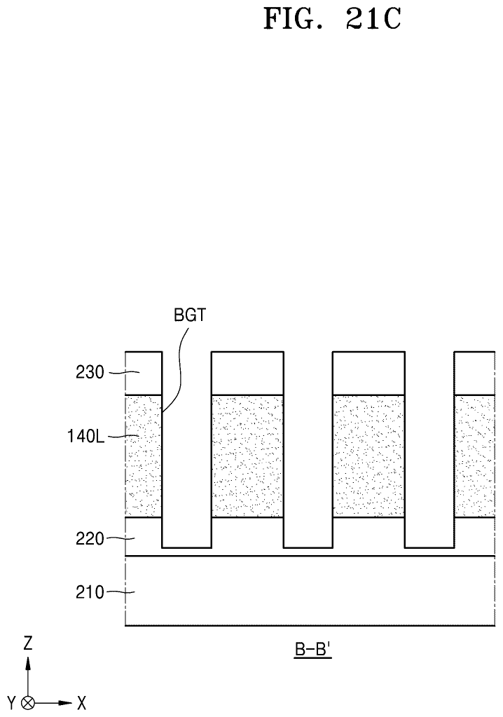

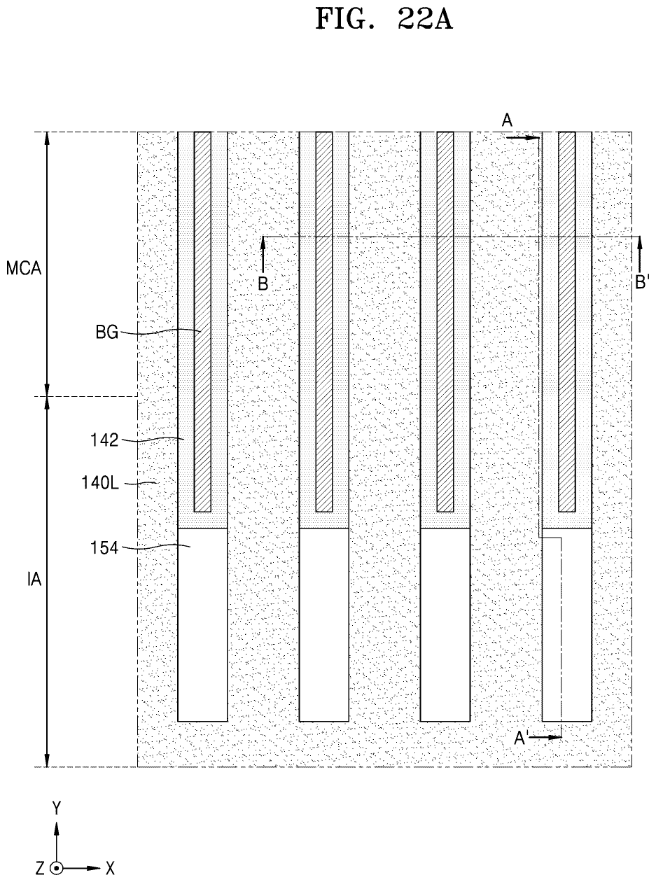

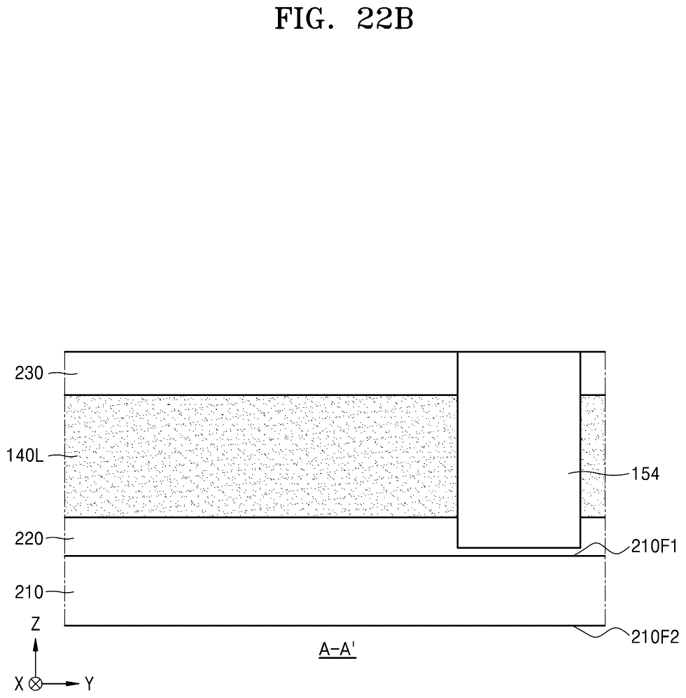

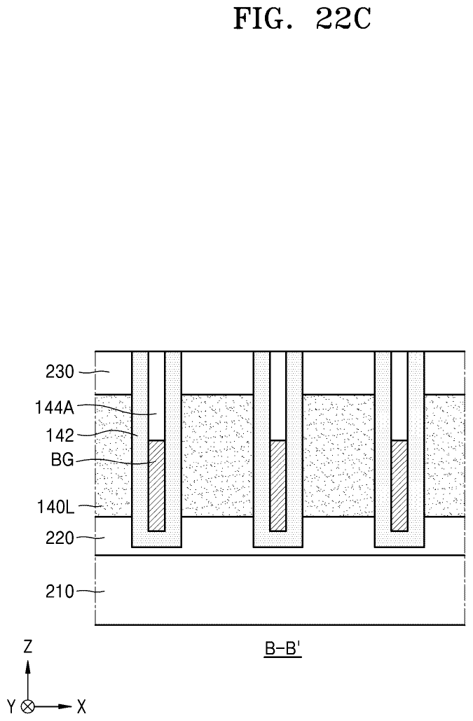

FIGS. 21A to 22C are schematic diagrams showing a method of manufacturing a semiconductor device 100, according to an example embodiment, wherein FIGS. 21A and 22B are top views based on the process sequence, FIGS. 21B and 22B are cross-sectional views taken along line A-A′ in FIG. 2 based on the process sequence, and FIGS. 21C and 22C are cross-sectional views taken along line B-B′ in FIG. 2 based on the process sequence.

Referring to FIGS. 21A to 21C, a mask pattern in the shape of a line pattern extending in the second horizontal direction Y may be formed on the semiconductor layer 140L in the cell array area MCA and the interface area IA, and then a portion of the semiconductor layer 140L may be removed using the mask pattern to form a plurality of back gate trenches BGT.

Thereafter, an insulating block 154 may be formed using an insulating material within a portion of the plurality of back gate trenches BGT in the interface area IA. In some example embodiments, the insulating block 154 may have a desired (or alternatively, predetermined) width in the second horizontal direction Y from the ends of the plurality of back gate trenches BGT.

In some example embodiments, a cover mask may be formed to cover a portion of the cell array area MCA and the interface area IA, and an insulating block 154 may be formed in a portion of the back gate trench BGT that is not covered by the cover mask. In other example embodiments, an insulating block layer may be formed within the entire back gate trench BGT in the cell array area MCA and the interface area IA, and a cover mask may be formed to cover a portion of the interface area IA. Then, the insulating block layer not covered by the cover mask may be removed from other portions of the cell array area MCA and the interface area IA, leaving the insulating block 154 within a portion of the interface area IA.

Referring to FIGS. 22A to 22C, the back gate insulating layer 142 and the back gate line BG may be formed in a portion of the cell array area MCA and the interface area IA.

Afterwards, a portion of the back gate line BG disposed above the back gate trench BGT may be removed, and the first back gate capping layer 144A may be formed on the back gate line BG using an insulating material. In some example embodiments, the first back gate capping layer 144A may include silicon nitride.

Thereafter, the semiconductor device 100 may be completely formed by performing the processes described with reference to FIGS. 13A to 20D.

According to some example embodiments, an insulating block 154 may be disposed in the interface area IA at a position overlapping a plurality of back gate lines BG in the second horizontal direction Y, and a word line contact WLC may be formed on the insulating block 154 and the word line WL. Therefore, in the process of forming the word line contact WLC, the misalignment margin for placement of the word line contact WLC may be relatively large.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate including a cell array area and an interface area, the cell array area being at at least one side of the cell array area;
a plurality of bit lines on the cell array area of the substrate and extending in a first horizontal direction parallel to an upper surface of the substrate;
a plurality of back gate lines being at a higher vertical level than the plurality of bit lines and extending in a second horizontal direction intersecting the first horizontal direction;
a plurality of insulating blocks on the interface area of the substrate, each of the plurality of insulating blocks overlapping a corresponding one of the plurality of back gate lines in the second horizontal direction;
a plurality of word lines among which each pair of two adjacent word lines are on two opposite sides of a corresponding one of the plurality of back gate lines, respectively, each of the plurality of word lines extending on a sidewall of a corresponding one of the plurality of insulating blocks in the second horizontal direction;
a plurality of active semiconductor layers, each of the plurality of active semiconductor layers being between an adjacent pair of one of the plurality of back gate lines and one of the plurality of word lines on the cell array area of the substrate, each of the plurality of active semiconductor layers having one end electrically connected to a corresponding one of the plurality of bit lines; and
a word line contact on the interface area of the substrate, the word line contact being on a corresponding word line, among the plurality of word lines, and being on a corresponding insulating block, among the plurality of insulating blocks, adjacent to the corresponding word line.

2. The semiconductor device of claim 1, further comprising:
a back gate insulating layer surrounding a sidewall of each of the plurality of back gate lines and between the plurality of back gate lines and the active semiconductor layer adjacent thereto,
wherein a sidewall of the back gate insulating layer is aligned with the sidewall of the insulating block.

3. The semiconductor device of claim 2, further comprising:
a plurality of dummy active semiconductor layers, each of the plurality of dummy active semiconductor layers being between an adjacent pair of a corresponding one of the plurality of back gate lines and a corresponding one of the plurality of word lines on the interface area of the substrate; and
a back gate contact on the interface area of the substrate and on a corresponding one of the plurality of back gate lines at a position overlapping a corresponding one of the plurality of dummy active semiconductor layers in the first horizontal direction.

4. The semiconductor device of claim 3,
wherein a first gap between two adjacent ones of the plurality of word lines that are between two adjacent ones of the plurality of insulating blocks in the interface area is greater than a second gap between two adjacent one of the plurality of word lines that are between two adjacent ones of the plurality of back gate lines in the interface area.

5. The semiconductor device of claim 3,
wherein a first gap between two adjacent ones of the plurality of word lines that are between two adjacent ones of the plurality of insulating blocks in the interface area is greater than a third gap between two adjacent ones of the plurality of word lines that are between two adjacent ones of the plurality of back gate lines in the cell array area.

6. The semiconductor device of claim 3, wherein the back gate insulating layer is between each of the plurality of back gate lines and one of the plurality of dummy active semiconductor layers corresponding thereto.

7. The semiconductor device of claim 3,
wherein the back gate contact does not vertically overlap each of the plurality of insulating blocks, and
the word line contact does not vertically overlap each of the plurality of back gate lines and the back gate insulating layer.

8. The semiconductor device of claim 1, wherein the plurality of active semiconductor layers include silicon, germanium, or silicon germanium.

9. The semiconductor device of claim 1,
wherein the word line contact includes
a first word line contact on a first word line among the plurality of word lines and
a second word line contact on a second word line among the plurality of word lines and being offset from the first word line contact in the second horizontal direction.

10. The semiconductor device of claim 1,
wherein ends of the plurality of word lines are spaced apart from ends of corresponding ones of the plurality of back gate lines by a first horizontal distance in the second horizontal direction, and
a sidewall of the word line contact is spaced apart from an end of a corresponding one of the plurality of back gate lines by a second horizontal distance that is less than the first horizontal distance in the second horizontal direction.

11. The semiconductor device of claim 1, further comprising
a peripheral circuit transistor on the upper surface of the substrate, and
wherein the plurality of bit lines are at a vertical level higher than the peripheral circuit transistor based on the upper surface of the substrate.

12. A semiconductor device comprising:
a substrate including a cell array area and an interface area, the interface area being at at least one side of the cell array area;
a plurality of bit lines on the cell array area of the substrate and extending in a first horizontal direction parallel to an upper surface of the substrate;
a plurality of back gate lines being at a higher vertical level than the plurality of bit lines and extending in a second horizontal direction intersecting the first horizontal direction;
a plurality of insulating blocks on the interface area of the substrate and each of the plurality of insulating blocks overlapping a corresponding one of the plurality of back gate lines in the second horizontal direction;
a plurality of word lines among which each pair of two adjacent word lines are on two opposite sides of a corresponding one of the plurality of back gate lines, respectively, each of the plurality of word lines extending on a sidewall of a corresponding one of the plurality of insulating blocks in the second horizontal direction;
a plurality of active semiconductor layers, each of the plurality of active semiconductor layers being between an adjacent pair of one of the plurality of back gate lines and one of the plurality of word lines on the cell array area of the substrate, each of the plurality of active semiconductor layers having one end electrically connected to a corresponding one of the plurality of bit lines;
a back gate contact on the interface area of the substrate and on a corresponding one of the plurality of back gate lines; and
a word line contact on the interface area of the substrate and electrically connected to a corresponding one of the plurality of word lines at a position vertically overlapping a corresponding one of the plurality of insulating blocks,
wherein the word line contact is spaced apart from a corresponding one of the plurality of back gate lines in the second horizontal direction.

13. The semiconductor device of claim 12, further comprising:
a back gate insulating layer between sidewalls of each of the plurality of back gate lines and one of the plurality of active semiconductor layers adjacent thereto; and
a plurality of dummy active semiconductor layers each being between each of the plurality of back gate lines and one of the plurality of word lines adjacent thereto and on the interface area of the substrate.

14. The semiconductor device of claim 13, wherein the back gate insulating layer is between each of the plurality of back gate lines and one of the plurality of dummy active semiconductor layers adjacent thereto.

15. The semiconductor device of claim 13,
wherein the back gate contact does not vertically overlap each of the plurality of insulating blocks, and
the word line contact does not vertically overlap each of the plurality of back gate lines and the back gate insulating layer.

16. The semiconductor device of claim 12,
wherein a first gap between two adjacent ones of the plurality of word lines that are between two adjacent ones of the plurality of insulating blocks in the interface area is greater than a second gap between two adjacent ones of the plurality of word lines that are between two adjacent ones of the plurality of back gate lines in the interface area.

17. The semiconductor device of claim 12,
wherein ends of the plurality of word lines are spaced apart from ends of corresponding ones of the plurality of back gate lines by a first horizontal distance in the second horizontal direction, and
a sidewall of the word line contact is spaced apart from an end of a corresponding one of the plurality of back gate lines by a second horizontal distance that is less than the first horizontal distance in the second horizontal direction.

18. The semiconductor device of claim 12,
a peripheral circuit transistor on the upper surface of the substrate, and
wherein the plurality of bit lines are at a vertical level higher than the peripheral circuit transistor based on the upper surface of the substrate.

19. A semiconductor device comprising:
a substrate including a cell array area and an interface area, the interface area being at at least one side of the cell array area;
a peripheral circuit transistor on an upper surface of the substrate;
a plurality of bit lines on the cell array area of the substrate, being at a vertical level higher than the peripheral circuit transistor, and extending in a first horizontal direction parallel to the upper surface of the substrate;
a plurality of back gate lines at a higher vertical level than the plurality of bit lines and extending in a second horizontal direction intersecting the first horizontal direction;
a plurality of word lines among which each pair of two adjacent word lines are on two opposite sides of a corresponding one of the plurality of back gate lines, respectively, the plurality of word lines extending in the second horizontal direction;
a plurality of active semiconductor layers, each of the plurality of active semiconductor layers being between an adjacent pair of one the plurality of back gate lines and one of the plurality of word lines on the cell array area of the substrate, each of the plurality of active semiconductor layers having one end electrically connected to a corresponding one of the plurality of bit lines;
a plurality of dummy active semiconductor layers between each of the plurality of back gate lines and one of the plurality of word lines adjacent thereto, and on the interface area of the substrate;
a back gate insulating layer between sidewalls of each of the plurality of back gate lines and a corresponding one of the plurality of active semiconductor layer adjacent thereto;
an insulating block on the interface area of the substrate, spaced apart from a corresponding one of the plurality of back gate lines, and having a sidewall aligned with the back gate insulating layer;
a back gate contact on the interface area of the substrate and on a corresponding one of the plurality of back gate lines; and
a word line contact on the interface area of the substrate and electrically connected to a corresponding one of the plurality of word lines at a position vertically overlapping a corresponding one of the plurality of insulating blocks.

20. The semiconductor device of claim 19,
wherein the back gate contact does not vertically overlap the insulating block, and the word line contact does not vertically overlap each of the plurality of back gate lines and the back gate insulating layer.
